(19) United States
(12) Patent Application Publication
(10) Pub. No.: US 2010/0171518 A1
(43) Pub. Date: Jul. 8, 2010

(54) Method and apparatus for non-destructive detection of defects in composite laminate structures

(75) Inventors: Robert Bateman, Fredericton (CA); Jules J.C. Picot, Fredericton (CA)

Correspondence Address: DOWELL & DOWELL P.C., 103 Oronoco St., Suite 220, Alexandria, VA, 22314, US

(73) Assignee: University of New Brunswick

(21) Appl. No.: 12/654,313

(22) Filed: Dec. 16, 2009

Related U.S. Application Data
(60) Provisional application No. 61/193,692, filed on Dec. 16, 2008.

(51) Int. Cl. G01R 27/08

(52) U.S. Cl. 324/724

(57) ABSTRACT

The present invention provides a probe apparatus and method as described below for use as a non-destructive testing (NDT) device to detect and locate structural flaws in a composite laminate. In preferred embodiments, the method includes measuring effective thermal conductivity (Ke) of the laminate using one contact surface, non-invasively. The device is preferably portable and battery-operated. The thermal conductivity method on which the device is based is much simpler to use than the known devices for NDT and allows the utilization of a direct correlation between thermal conductivity and mechanical strength in the case of polymer composites. The device may also be used for process control in manufacturing and monitoring materials in service.

### CROSS-REFERENCE TO RELATED APPLICATION

This application claims priority to U.S. Provisional Application No. 61/193,692, filed on Dec. 16, 2008, the entire contents of which are incorporated herein by reference.

### FIELD OF THE INVENTION

The present invention relates to an apparatus and method for the non-destructive testing of composite laminate structures. More particularly, the present invention relates to a multiple element thermal conductivity probe for the detection of defects in composite laminate structures.

### BACKGROUND OF THE INVENTION

The detection of sub-surface defects is critical to the long-term viability of many types of composite laminate structures and the reliability and risk management of many manufacturing processes. For example, composite laminates involving outer layers of carbon fiber reinforced polymer (CFRP), with its high strength-to-weight ratio, have been used in a wide variety of applications, and the long-term monitoring of the integrity of the laminate bond can be of critical importance.

Composite laminate structures are often used with many different types of core materials, including concrete and foam. For example, CFRP may be applied to form foam laminate panels or struts in which laminates are made from outer layers of woven or knitted continuous carbon (or glass) fiber separated by a closed-cell foam core, with the assembly cemented together by epoxy resin. This type of material is used currently in the construction of structural components for new aircraft (for example, 20% of the structure of the Airbus A-380, and 69% for the Boeing 787 Dreamliner), as well as in new high-speed naval patrol vessels, power wind turbine blades, and bridge structures. The aircraft or watercraft obtains high tensile strength from the outer layers, and high compression strength from the closed cell foam. Flaws due to layer separation and/or failure of the outer skins by sharp impacts change the thermal conductivity of the material.

At present, methods of non-destructively testing or monitoring, in situ, of sub-surface defects in composite laminate materials are expensive and cumbersome. For example, several instruments currently used for this purpose include: (1) ultrasonic, (2) dynamic thermography, and (3) X-ray analysis instrumentation, which are all very costly. In addition, the first method requires immersion of parts in a water bath, which is unrealistic for large parts such as wing flaps; the second depends on phase angle measurements at low frequency (which depends on thermal diffusivity); and the third requires the part to be placed in a small enclosure, again impossible for large parts.

Therefore it would be very advantageous to provide a simple, inexpensive probe device to monitor sub-surface structural features in composite laminate materials such as composite CFRP structures. For example, it is highly desirable to provide a method of detecting structural defects in CFRP/structural foam laminate panels or struts both during the process of construction of the panels and for determining the “health” of the panels in service.

### SUMMARY OF THE INVENTION

The present invention provides a method and apparatus described below for use as a non-destructive testing (NDT) device to detect and locate structural flaws beneath the surface of a composite laminate material by measuring effective thermal conductivity (Ke) of the material using one contact surface, non-invasively. The method may be adapted to be performed with a device that is portable and optionally battery-operated. In preferred embodiments, the method and device are configured for the detection of structural defects within composite laminate materials such as CFRP laminates. The thermal conductivity method on which the device is based is much simpler to use than the known devices for NDT and utilizes the direct correlation between thermal conductivity and mechanical strength in the case of polymer composites. The device may also be used for process control in manufacturing and monitoring materials in service.

An embodiment of the present invention provides a device for the non-destructive testing of a composite laminate material, the device comprising:

a) an array of elongate conductive resistance elements affixed to a surface of an insulating substrate, the elements being spaced a known distance from each other, the insulating substrate supported by an insulating backing material, and the elements having a composition and cross-sectional dimensions selected to generate heat when an electric current is passed therethrough;

b) a power supply, the elements being connected to the power supply for supplying electrical current thereto to provide a controlled rate of heat generation when the array is contacted with an outer surface of the composite laminate material;

c) means for measuring a time-dependent resistance of each the element when the electrical current is supplied to each the element; and

d) a computer control means being connected to the power supply and the means for measuring a time-dependent resistance, the computer control means programmed to monitor and record changes in the resistance of the each element with time and provide an output related to an effective thermal conductivity of the composite laminate near each the element.

The computer controller means may be programmed to apply current to each of said elongate electric current-carrying metal elements either simultaneously or sequentially according to another prearranged sequence. The polymer sheet may be flexible and can be shaped to a non planar composite laminate material, such as a CFRP/structural foam laminate.

In another embodiment there is provided a method of non-invasive and non-destructive testing for assessing viability and structural integrity of composite laminate material (such as a CFRP/structural foam laminate), comprising the steps of:

a) contacting a probe with a surface of the composite laminate, the probe comprising at least one conductive resistance element affixed to a surface of an insulating substrate, the insulating substrate supported by an insulating backing material, and the element having a composition and cross-sectional dimensions selected to generate heat when an electric current is passed therethrough;

b) applying a current to the element for a time duration and measuring a voltage of the element while applying the current;

c) processing the time-voltage measurements to obtain an output measure related to an effective thermal conductivity of the sample, and

d) comparing the output measure to an expected value and inferring the presence or absence of a structural defect beneath the surface of the composite laminate.

The device can be used for non-destructive testing (NDT) and monitoring of structures, provided that the defect is sufficiently close to the composite laminate surface to be affected by a thermal wave propagating inward from the surface. The method and apparatus are particularly useful in monitoring composite laminate materials forming structures used in, but not limited to, ships, power turbine blades, bridge structures and aircraft, to mention just a few.

A further understanding of the functional and advantageous aspects of the invention can be realized by reference to the following detailed description and drawings.

### BRIEF DESCRIPTION OF THE DRAWINGS

The invention will now be described, by way of non-limiting examples only, reference being made to the accompanying drawings, in which:

FIG. 1 shows a cross-sectional view of a sample of carbon fiber reinforced polymer (CFRP)/structural foam laminate with surface layers of carbon fiber bonded to a closed-cell foam.

FIG. 2 shows a top view of an electrode array mounted on a flexible polymer sheet which in turn is affixed to a polyurethane foam backing for insulation and support.

FIG. 3 shows the entire probe system for testing the thermal properties of structural foam laminates in which the structural foam being tested is spaced above the array of heating elements, while in operation the foam is sitting directly on top of the heater element array.

FIG. 4 shows a plot of measured temperature rise vs. natural log of time for normal and axial direction.

FIG. 5 shows a flow chart illustrating a method according to a preferred embodiment of the invention

FIG. 6 shows a photograph of a multi-element probe according to an embodiment of the invention.

FIG. 7 shows a calibration curve for the multiple probe apparatus.

FIG. 8 shows a photograph of a sample in which a waterslot defect is incorporated.

FIG. 9 is a plot of temperature vs. natural logarithm (ln(t)) of time from simultaneous measurements using various probes of the probe array;

FIG. 10 shows the penetration plot for the sample incorporating a waterslot defect.

FIG. 10 shows the effective Ke for each probe (9, 8, 7, or 6 out of ten probes numbered 1 to 10) calculated from equation (3) from slopes taken from FIG. 9 at ln(t) of 2.5; 3.5; 4.5; and 5.5; respectively, corresponding 5% penetration distances are calculated using equation (4) at each ln(t) value, and probe 8 and 7 results are from the uniform zone of the sample and their mean is used as Ke, ref for normalization.

FIG. 11 shows a plot of Ke after flex test deformation divided by Ke, ref (before deformation) plotted vs. penetration into the foam directly below a single probe, showing a gradual decrease in the tension zone near the top CFRP layer followed by an increase as penetration moves into the crushed zone.

FIG. 12 shows a simulation grid used in numerical simulations.

FIG. 13 plots the simulated temperature rise curve for a waterslot sample.

FIG. 14 plots the simulated temperature rise curve for a neighbouring probe when detecting a waterslot sample.

FIG. 15 is a sample temperature contour produced by the simulator.

FIG. 16 shows a photo of the 1.0 cm thick core with 3 mm diameter hexagonal cells. A 1 cm by 8 cm section of the core was filled with plastic wood.

FIG. 17 shows the inferred temperature rise when the probe is placed (a) directly over a continuous section of plastic wood and (b) a 3 mm diameter hole.

FIG. 18 shows a photo of a composite laminate structure in which a portion of the structure exhibits delamination.

FIG. 19 plots the probe temperature rise for areas along the composite laminate structure with various degrees of delamination.

FIG. 20 shows a photograph of a composite laminate structure incorporating a void configured to be placed at a variable depth.

FIG. 21 plots the calculated Ke values at various sub-surface depths.

FIG. 22 is a photograph of a half-cylinder section of Diab foam.

FIG. 23 plots the temperature rise of the probe for the half-cylinder foam sample.

FIG. 24 shows experimental temp rise results for Nanogel at atmospheric pressure.

FIG. 25 shows simulation results for the Nanogel at atmospheric pressure.

FIG. 26 plots the normalized inverse slope, showing the sensitivity comparison for guarded and unguarded operation.

FIG. 27 shows the sample temperature contour of the unguarded probe simulation (temperatures are degrees Kelvin above 300 Kelvin).

FIG. 28 shows the sample temperature contour of the guarded probe simulation (temperatures are degrees Kelvin above 300 Kelvin).

FIG. 29 plots a simulated temperature rise curve for a sample with T.C.=0.5×10⁻³ W/mK.

FIG. 30 shows the simulated heating and cooling curves for a sample with a thermal conductivity of 1.0e-6 W/mK.

FIG. 31 shows the simulated heating and cooling curves for a sample with a thermal conductivity of 2.5e-6 W/mK.

FIG. 32 shows the simulated heating and cooling curves for a sample with a thermal conductivity of 1.0e-5 W/mK.

FIG. 33 shows the simulated heating and cooling curves for a sample with a thermal conductivity of 2.5e-5 W/mK.

FIG. 34 shows the simulated heating and cooling curves for a sample with a thermal conductivity of 5.0e-5 W/mK.

FIG. 35 shows the simulated heating and cooling curves for a sample with a thermal conductivity of 5.0e-4 W/mK.

FIG. 36 shows the simulated heating and cooling curves for a sample with a thermal conductivity of 5.0e-3 W/mK.

FIG. 37 shows the simulated heating and cooling curves for a sample with a thermal conductivity of 10e-3 W/mK.

FIG. 38 shows the simulated heating and cooling curves for a sample with a thermal conductivity of 27.6e-3 W/mK.

FIG. 39 plots the simulated hysteresis, showing integrated cooling temperature minus integrated heating temperature.

FIG. 40 shows the effect of a variation in contact resistance on the measured temperature rise curves and corresponding slopes.

### DETAILED DESCRIPTION OF THE INVENTION

Generally speaking, the systems described herein are directed to a device for the non-destructive detection of sub-surface detects in composite laminate structures. As required, embodiments of the present invention are disclosed herein. However, the disclosed embodiments are merely exemplary, and it should be understood that the invention may be embodied in many various and alternative forms. The Figures are not to scale and some features may be exaggerated or minimized to show details of particular elements while related elements may have been eliminated to prevent obscuring novel aspects. Therefore, specific structural and functional details disclosed herein are not to be interpreted as limiting but merely as a basis for the claims and as a representative basis for teaching one skilled in the art to variously employ the present invention. For purposes of teaching and not limitation, the illustrated embodiments are directed to a multiple element thermal conductivity probe to measure the viability of CFRP/structural foam laminates.

As used herein, the term “about”, when used in conjunction with ranges of dimensions, angles or other physical properties or characteristics, is meant to cover slight variations that may exist in the upper and lower limits of the ranges as to not exclude embodiments with concentrations slightly above or below those recited herein. It is not the intention to exclude embodiments such as these from the present invention.

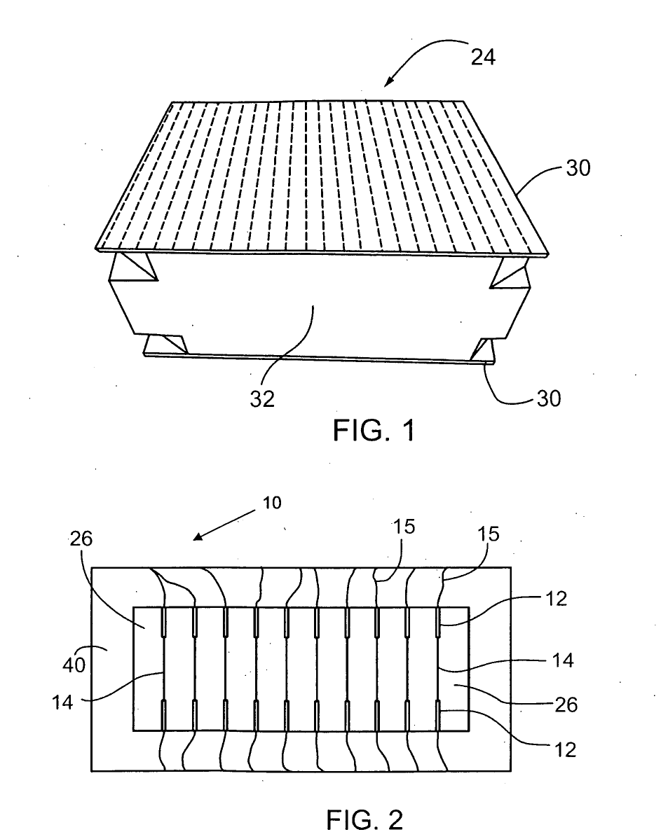

A preferred embodiment of the invention is illustrated in FIG. 1, where a typical composite laminate structure is shown generally at 24. While those skilled in the art will readily appreciate that the embodiments disclosed herein are applicable to a wide variety of composite laminate structures, specific embodiments are illustrated within the context of foam core composite laminates. As mentioned above, typically, structural foam laminates consist of outer surfaces of fiber/resin composites (e.g. carbon fiber impregnated with polymer resin (CFRP)) bonded (by polymer resin) to a core of structural foam (e.g. polyvinyl chloride (PVC) closed cell) (see FIG. 1). FIG. 1 shows a sample of typical CFRP/structural foam laminate 24 which includes a foam core (for example, Diab H-80 PVC closed-cell foam) 32 with surface layers 30 of a reinforced composite material (for example, Vectorply CBX-2400 carbon fiber). The reinforced composite is bonded to the foam 32, thereby forming the composite laminate structure. The dashed lines on surface layers 30 represent biaxial weave binder filaments typical of many reinforced composite layers.

While the dimensions of the composite laminate structure 23 may be varied depending on the application, a typical reinforced composite surface layer is about 1 mm thick and a typical foam layer is about 5 cm thick. It will be understood that the dimensions for the various layers are only examples of embodiments that have been tested and are not to be interpreted as limiting the scope of the invention. The probe 10, shown in FIG. 2, may be made with a wide variety of dimensions of the elements 14, including length and width, depending on the surface area of the material being tested. Similar reasoning applies for spacing of the elements 14 from each other.

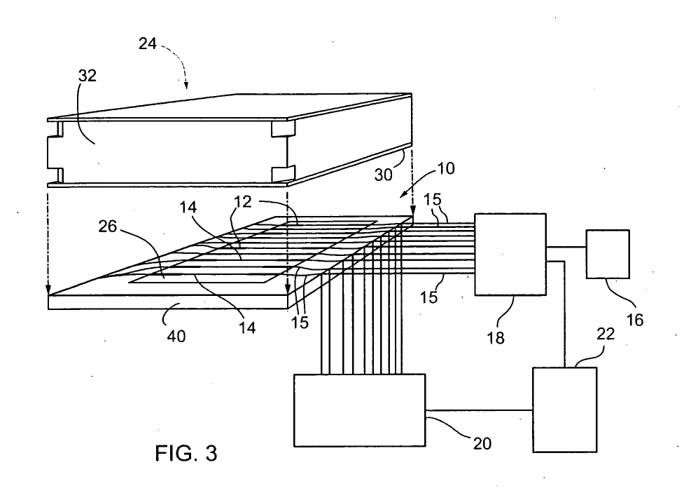

Referring now to FIG. 3, the surface layers 30 provide high tensile strength and the foam core 32 provides high compressive strength. Such laminates are extensively used for load-bearing structural components in modern aircraft, as well as in new high-speed naval patrol vessels and other watercraft, power wind turbine blades, and bridge structures. The probe apparatus and methods described herein involve the non-destructive testing (NDT) of the composite laminate to detect and locate structural flaws in the laminate by measuring effective thermal conductivity (Ke) of the laminate using one contact surface, non-invasively. In a preferred embodiment, the device is portable and battery-operated.

The device for monitoring the structural integrity of foam structures/laminates constructed in accordance with the present invention includes an array of conductive resistance elements, preferably provided as linear electric current-carrying narrow, thin, film elements (such as a metal film) 14 situated on a thin insulating substrate, such as a polymer film sheet 26. Each element is formed with dimensions and a material type selected to generate a small resistance and generate heat when subjected to an electric current. Unlike prior art devices, the multi-element array disclosed herein provides an inventive design that allows for defects to be rapidly identified based on a single, rapid measurement. The use of a multi-element probe, with the probes spaced over a large area, can be particularly useful in obtaining rapid results with excellent spatial repeatability, and is well suited to large parts or structures. The spacing of the probe elements may vary depending on the application, and one skilled in the art will readily appreciate that the resolution of the probe will be determined in part by the spacing of the probe elements. While a preferred spacing range is within 1-5 cm, a wide range of probe element spacings may be employed to detect various structural defects.

In this non-limiting embodiment (FIG. 2) the conductive resistance elements 14 are 5 cm in length and are parallel to one another at a spacing of 2.5 cm and are connected to a current controller 18 (FIG. 3) by wire end terminals 12 connected to both ends of conductive resistance elements 14 which are connected to controller 18 by wires 15. This array is bonded to a 5 cm thick flexible insulating backing material 40 (preferably polyurethane foam but not limited thereto) which acts as an insulating layer and support. The properties of the foam 40 layer are taken into account in the calibration procedure. A test sample such as laminate 24 is placed over the probe element system conductive elements 14, thin polymer thin sheet 26, and polyurethane foam 40 during a test. FIG. 3 shows the complete probe system generally at 10 which includes a battery power supply 16, an electric current controller 18, a data acquisition system 20 for monitoring the resistance of the elements shown in contact with a FRP/structural foam laminate sample 24, and a control means 22. The control means 22 may be a computer or computer processor/microprocessor or dedicated control unit preprogrammed.

While a wide range of probe range diameters may be used, the probe wires are preferably high aspect ratio ribbons, such as a ribbon with a width greater than approximately 100 microns (preferably about 200 microns), a thickness of less than approximately 1 micron (preferably about 0.25 microns), and a length that is preferably within the range of about 1-5 centimeters. Preferably, the dimensions of the probe element are selected to minimize the required current for a given heat emission rate.

The wire material is preferably a nickel alloy deposited on a poly-imide film, where the poly-imide film is about 0.051 millimeters thick. Such dimensions enable a portable system with low power consumption, and less susceptibility to end heat loss.

With these preferred parameters, the wire resistance at 20° C. was 110Ω. The temperature resistance coefficient was found after calibration to be 0.00340 per degree Celsius for the range of 5° C. to 35° C. The wire current was typically about 0.020 amps. A slope error of 1.0% was estimated for wire end effect and was ignored for this work.

According to an embodiment of the invention, heat emission rates are preferably within the range of approximately 0.005 W/cm of wire length to 0.040 W/cm. The inventors have found that in this case, temperature rises of more than 5 Celsius are avoided. Furthermore, a short wire length, (for example, 1.0 cm) is more sensitive to small flaws than a longer wire length (for example, 5 cm) because thermal conductivity differences are averaged out for the complete length of the wire. As will be discussed in the examples below, a 3 mm diameter hole in a core material directly beneath a glass fiber outer laminate is readily detected by a 1.0 cm long wire, but not by a 5 cm long wire. Wire end heat loss is greater for wires of greater cross-section. For the geometries and sizes discussed above, the effect on temperature measurement is that temperature readings are typically 1.0% lower. This is preferably taken into account by the calibration procedure.

While FIG. 3 shows the structural foam 24 to be tested spaced above the probe system 10, during testing the foam 24 is sitting directly on top of the heater element array. In a preferred embodiment, external pressure may be applied to provide improved thermal contact between the probe and the surface of the composite laminate. It will be understood that the dimensions of the heater elements and their spacing is not limited to the values given above, nor do they need to be arrayed in parallel; they can take any configuration which is accounted for in doing the calculations.

The computer controller 22 controls the electrical current supplied to each element 14 to give a controlled (constant or variable) rate of heat generation with time to each element 14, either simultaneously or according to another prearranged sequence. The computer 22 in conjunction with the data analyzer 20 measures voltage readings across each element 14 at one second or shorter intervals after start of heating and converts these to probe temperature rise values. These are plotted versus logarithm of time and the slopes of the curve are calculated as time progresses. The computer controller may reside in a computer, such as a laptop, or may comprise a computer processor (and related systems such as memory and input/output devices) residing in a portable device such as a personal digital assistant.

Thermal conductivity is inversely proportional to this slope and directly proportional to the known heat output of the wire and is found from probe calibration. The zone of influence of each probe during an experiment depends on the progression of the continuous heat step input through the material, and since this is known mathematically, the computer provides values of effective thermal conductivity as a function of distance from each element 14. As discussed below, a computer algorithm is used to convert these values to effective Ke as a function of penetration of the heat pulse into the laminate 24 and provides values of effective thermal conductivity as a function of distance from each element 14. Changes in Ke as penetration proceeds are related to the properties of the materials (and their condition) within the laminate 24. An image of these values is produced in plot form.

In the non-limiting examples used herein, CFRP outer layers consist of woven carbon fiber cloth and the core is a rigid closed-cell polyvinyl chloride (PVC) foam. Epoxy resin is introduced in a resin transfer process to impregnate the carbon fiber cloth and bond it to the foam core, as shown in FIG. 1.

The response to a steady heat output from a linear narrow thin film probe of the type above is well known for the case where the probe with its insulating support is placed against a sample surface to be measured. Assuming that both sample and backing are subject to the same temperature history at the heating element interface, the following result will obtain when thermal conductivity of sample and backing are uniform and isotropic throughout but may be different one from the other²:

dT/d ln(t)=Q/(2π(Kb+Ks) (1)

For a uniform material sample, the value of the slope dT/d ln(t) is constant after a 5 second time delay after the start of heating for these probes. Ks is thermal conductivity of the sample and Kb that of the backing material, while Q is heat released per unit time per unit length of the heating element. Because of the presence of the thin polymer film 26 supporting the elements 14, the probe is calibrated using a number of materials of known (also uniform and isotropic) Ks, using a constant value of Q with time, and keeping temperature rise below 5° Celsius. A typical result for the probes herein operating at a Q=0.992 W/m is as follows³:

dT/d ln(t)=−0.0047(Ke+0.041)⁻²+0.2047(Ke+0.041)⁻¹; R²=0.996 (2)

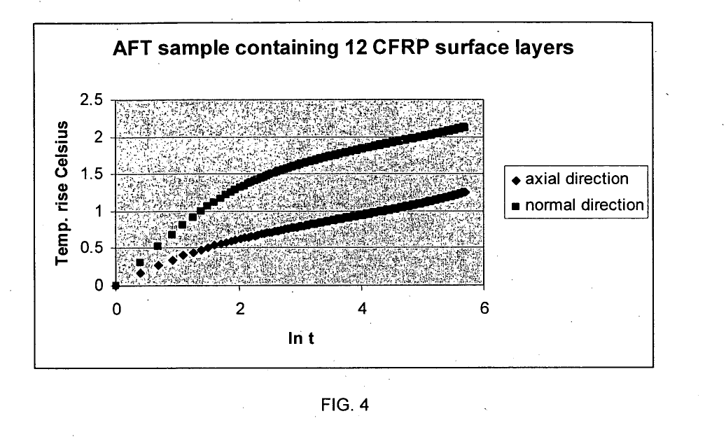

To illustrate selected embodiments of the invention, a 12-layer assembly of the CFRP surface sheet was tested with a single probe element 14, first with the probe surface placed against the edge of the 12-layer sample, then with the probe placed against the face of the assembly. Results are shown in FIG. 4. The normal direction test exhibits a Ke of 0.40 W/mC for the period 5 to 8 seconds with a gradual increase to 1.25 W/mC for the period 55 to 150 seconds. The axial direction test exhibits a constant Ke of 1.30 W/mC for the period 5 to 150 seconds. This means that even though heat is conducted initially in the normal direction into the CFRP, it is then directed along the surface in an axial direction with the result that axial conduction is controlling the heat conduction process. This is due to the inherent anisotropy of the carbon fibers and their orientation.

A single thickness of CFRP as in FIG. 1 will act as an extension of the probe element, directing heat along the surface away from the element and is therefore sensitive to changes in thermal properties of CFRP and/or structural foam as the heat wave penetrates into the laminate. Flaws in the laminate will be detected by changes in slope of the T vs. ln(t) graph. Using the analogy of one-dimensional heat conduction along the CFRP layer with loss of heat to the surrounding foam, we calculate the penetration distance of the heat wave along the surface (or into the foam) where temperature has reached 5% of the temperature measured by the heating element as follows¹:

5% pen′n=(4*α*t)^{0.5} (3)

Here α is thermal diffusivity (K/ρCp) of the CFRP (or foam) and t is time after start of the measurement where the slope of the T vs. ln(t) curve shows abnormal behaviour, indicating a change in material properties as the heat wave proceeds along the material. Changes in properties beyond the 5% position have minimal effect on the T vs. ln(t) curve.

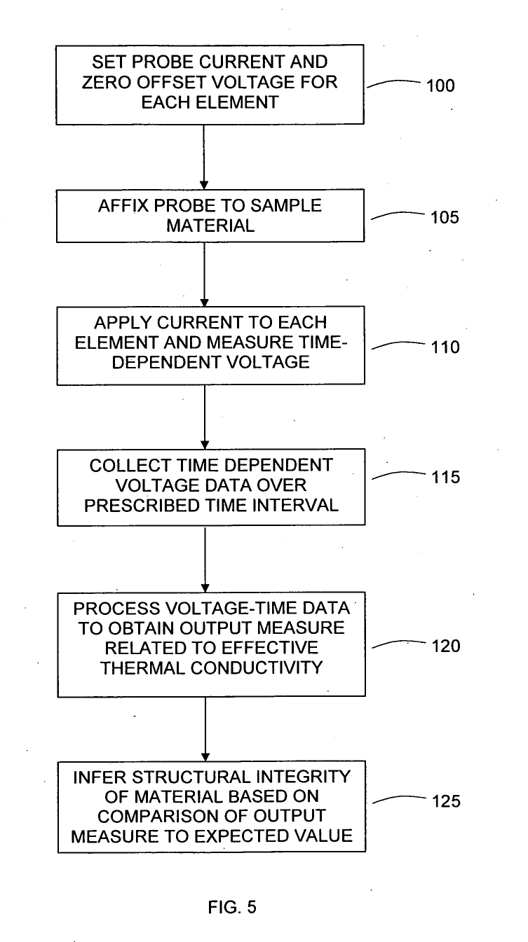

FIG. 5 illustrates a preferred embodiment of the invention in which a method is provided for inferring the structural integrity of, and/or detecting defects within, a composite laminate material, based on hot wire measurements. The method involves an apparatus as disclosed above, in which a probe comprising one or more hot wires mounted on a substrate is utilized to infer the presence or absence of structural defects beneath the surface of a material. In a preferred embodiment, the above flow chart is implemented in part by a computer processor programmed to carry out selected steps of algorithm.

In step 100, the probe current and zero offset voltages are selected. The probe current is selected to provide a heat emission rate that causes a small increase in the temperature of the sample. The temperature increase is preferably less than about 5° C., which typically ensures that the effect of the temperature sensitivity of the thermal conductivity on the results is minimized. The offset voltage may be optionally provided to cause time-dependent voltage changes to be recorded relative to a low baseline voltage, preferably near zero. This can be useful when amplifying the recorded voltage.

After contacting the probe with the sample surface in step 105, current is applied to the each probe element in step 110, which heat the sample and generate a thermal wave propagating within the sample. While applying the current to each probe element, the voltage of each element is monitored as a function of time in step 115. This voltage vs. time data, preferably obtained over several units of log time, is then collected and provided to a processor, which operates on the voltage-time data in step 120 to provide an output measure related to the effective thermal conductivity (as described below). The structural integrity is then assessed in step 125 (for example by visually interpreting graphical data or numerically based on a pre-defined data pattern or threshold) based on a comparison between the calculated output measure and an expected value for the output measure.

While the above flow chart prescribes inferring the structural integrity of the material based on processing the voltage-time results to obtain an output measure related to the effective thermal conductivity, it will be clear to one skilled in the art that a wide range of related output measures may be used to detect or infer structural information. In a simple example, the output measure may be the voltage-time graph, which can be assessed for kinks or changes in slope. Additional output measures include, but are not limited to, resistance-time results, temperature-time results, slope of the logarithmic voltage-time, resistance-time graph or temperature-time graph, effective thermal conductivity, depth dependence of the effective thermal conductivity, or any related parameter or parameter based on a combination thereof. In a preferred embodiment, the output measure is based on the depth dependence of the effective thermal conductivity, obtained using an inferred thermal depth such as the 5% temperature depth described above.

To obtain comparative measurements, the probe may be scanned relative to the sample surface, thereby obtaining a series of measured voltage-time data sets corresponding to various locations on the sample. Alternatively, or additionally, spatial data may be obtained from a probe comprising an array of spatially arranged hot wire elements, which each provide local spatial data relating to the sample. By comparing the data spatially (for example, by comparing each measure with an average of non-outlier measures), one may observe outlier data that is representative or suggestive of a structural defect. In a preferred embodiment, the probe readings are recorded and processed by a computer or processor that is programmed to identify structural defects based on voltage-time data falling outside of a prescribed range.

In another preferred embodiment, comparative data may be obtained based on historical measurements of the same structure presently being measured. This enables the operator to infer structural changes as a function of time, and to monitor any areas that begin to show departures from their historical data.

In yet another embodiment, comparative data may be obtained by using a reference value for the material being measured. For example, the reference value may be obtained from tabulated data, data obtained from measurements of a similar sample (for example, a production line sample), or alternatively a simulated value.

Preferably, as described above, the probe is initially calibrated with materials having a known effective thermal conductivity (accounting for the thermal conductivity of the insulating backing). Such a calibrated probe may then be employed to provide time dependent effective thermal conductivity values based on the knowledge of the temperature as a function of time and using equation (2) above. If the thermal diffusivity of the sample is also known, then the effective thermal conductivity may be plotted as a function of the 5% temperature distance within the sample, which provides a clearer representation of any suspected defects within the sample by estimating the depth of the defects.

The present device has several advantages over current testing devices. First, of the present devices in use for testing including 1) ultrasonic devices, 2) dynamic thermography devices, and 3) X-ray analysis, the present probe is very economic while the above instrumentation are all very costly. In addition, the first method requires immersion of parts in a water bath, which is unrealistic for large parts such as wing flaps; the second depends on phase angle measurements at low frequency (which depends on thermal diffusivity); and the third requires the part to be placed in a small enclosure, again impossible for large parts. The present device can be readily applied to large surface areas on one side of the panels, or may be permanently attached or embedded for monitoring as required.

The embodiments of the present invention provide improved thermal conductivity based methods and devices for non-destructive and non-invasive defect detection and process control. Most notably, the devices and methods disclosed herein are much simpler to use and address the well-known direct correlation between thermal conductivity and mechanical strength in the case of polymer composites (and other materials, as known to those skilled in the art). The device and methods forming various embodiments of the invention can be beneficially used for process control in manufacturing, detection of structural defects in new and old materials and structures, and continuous or discrete monitoring of materials and structures in service.

While several embodiments of the invention as disclosed herein have been presented as examples involving composite laminate structures comprising a foam core sandwiched between CFRP layers, the scope of the present invention is intended to encompass a broad class of composite laminate structures. For example, the present invention may also be adapted for use with composite laminates with alternative cores, such as concrete, or low thermal coefficient materials such as vacuum insulated panels.

The following examples are presented to enable those skilled in the art to understand and to practice the present invention. They should not be considered as a limitation on the scope of the invention, but merely as being illustrative and representative thereof.

### Example 1

### Detection of Defects in CFRP Composite Laminates

Flaw detection in sandwich type composite panels is of increasing importance in many different manufacturing industries such as aircraft, wind turbine and boat building. A polymer foam core reinforced on both sides with +/−45° biaxial carbon fiber cloth weave bonded with epoxy resin provides the basic structural elements in many cases.

This study is to evaluate the use of a multi element hot wire thermal conductivity (T.C.) probe as a non-destructive (NDT) testing method to locate and identify structural damage of this type of laminate. The focus in this study is a sandwich panel sample in which a water filled slot is introduced through one side of the sandwich and into the foam layer. This is to simulate a flaw along a boat hull which has filled with water while in use.

### Test Methods

The continuous heat output hot wire technique¹ is used with multiple hot wire elements placed along the undamaged side of the sandwich panel sample³. The 200 micron wide by 0.25 thick and 5 cm long elements are placed on the surface of a thin polyimide sheet in a parallel array spaced 2.5 cm apart. A backing material of polyurethane (PUR) foam 5.0 cm in thickness is used as an insulating support platform.

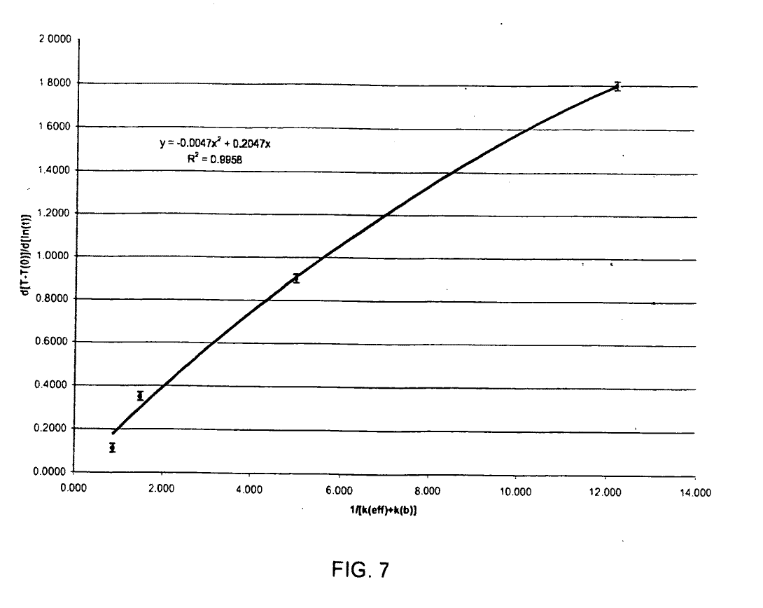

Measurements are done by placing sample materials over the probe assembly and calibration is done using materials of known thermal conductivity. FIG. 7 shows the calibration curve obtained with the materials shown in table 1:

TABLE 1
Calibration Points\ddot{3}

| standard | Slope | 1/(k(s) + k(b)) |
|---|---|---|
| PYREX | 0.1135 | 0.884 |
| Watergel | 0.3500 | 1.497 |
| PDMS | 0.9000 | 5.000 |
| PUR | 1.8000 | 12.195 |

The curve produces the following calibration equation that relates the thermal conductivity to the temperature rise slopes that are obtained from each hot wire element³: The k(s) are the sample thermal conductivities and k(b) is the thermal conductivity of the PUR backing material.

$${k}_{eff} = {[ 21.78 - \frac{\sqrt{0.0419 + {0.019}^{d [ T - {T}_{o} ] / d [ ln ( t ) ]}}}{0.009} ]}^{- 1} - 0.041 [ W / mK ] \qquad ( 4 )$$

where the value, k_{eff} is the net effect of the T.C. values encountered by the heat pulse as it leaves the wire, including anisotropic effects encountered through the carbon fiber layer. Since heat pulse penetration depends on time since the start of a test, the T vs ln(t) curves will show changes in slope in the case where there are different materials in a laminate. The k_{eff} therefore represents the combined effect of the T.C. values encountered within the zone of pulse penetration.

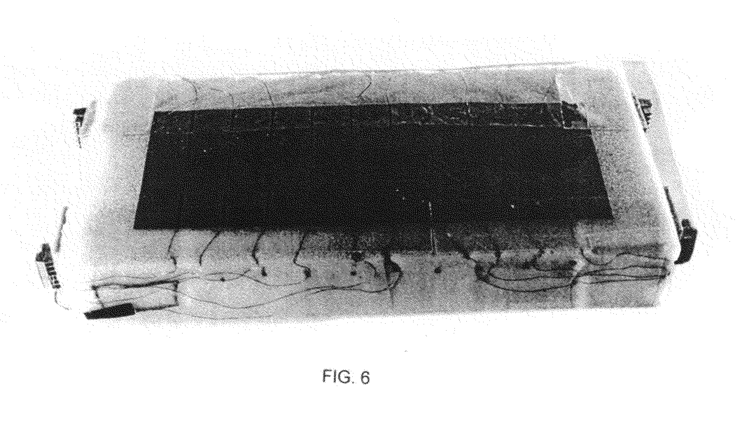

A 15 cm×25 cm test sample of structural foam laminate (CBX-2400 Vectorply as above with Diab H80 foam core) set up over the multi-element probe system shown in FIGS. 2 and 3 but with ten (10) conductive elements aligned side by side and numbered #1 to #10 consecutively (see photo in FIG. 6).

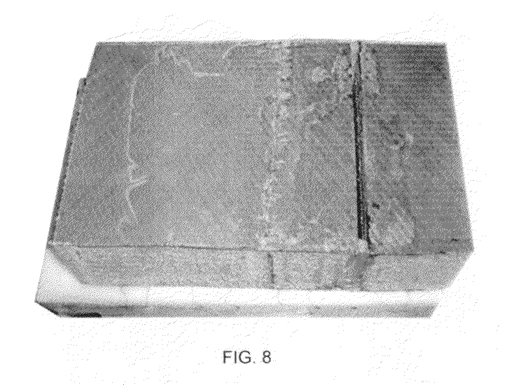

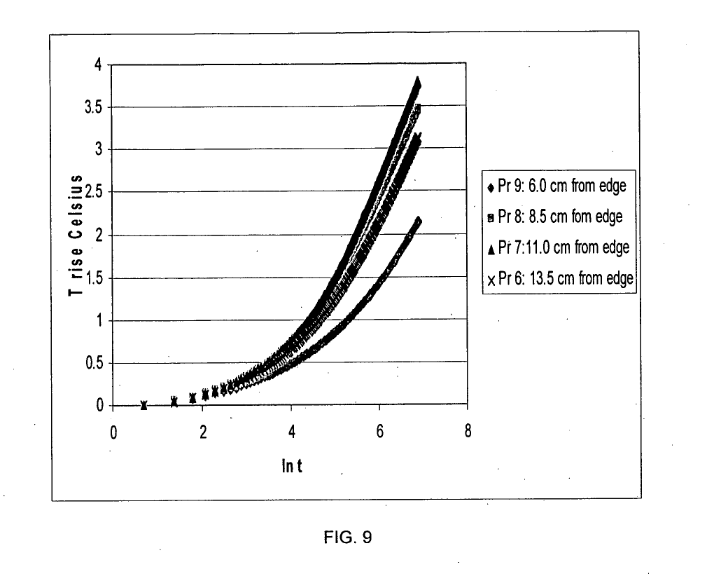

A sample of laminate used in boat building was chosen for testing. The waterslot experiment is designed to simulate a large crack that has formed and is subsequently filled with seawater. This sample (shown in FIG. 8) has a 5 mm wide slot cut into the top layer of fiber and down through the foam, up to but not including the bottom surface layer. The slot is filled with water gel. This sample is placed over the probe array with probe #9 directly below the water gel slot and probes #8, #7, and #6 oriented to the right with probe #6 a distance of 7.5 cms away from the slot. A butt weld in the foam core is situated 0.6 cm to the left of probe #6, consisting of a more dense 1.0 mm layer of bonding material traversing the foam zone between both outer CFRP layers and across the sample width. A simultaneous 4-probe experiment was done, and FIG. 9 shows the temperature rise results. (Metal weights were placed over the sample to provide good contact between sample and probes).

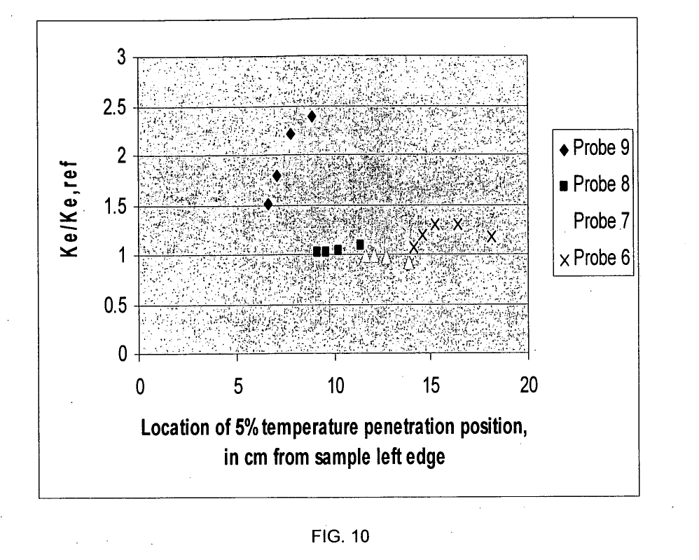

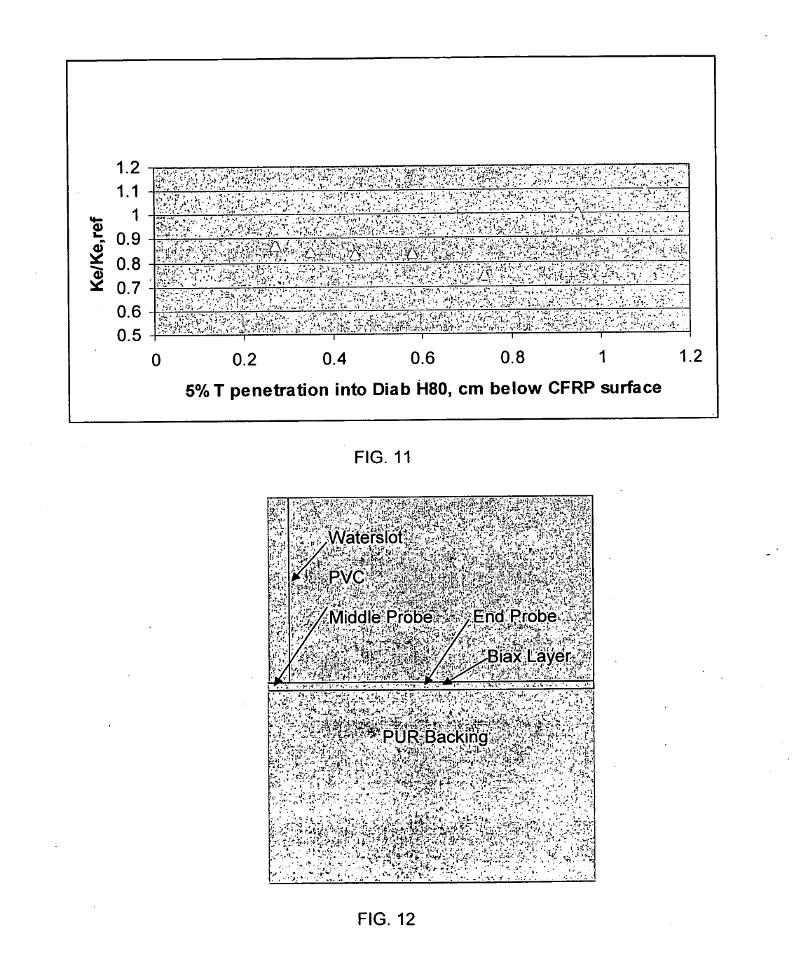

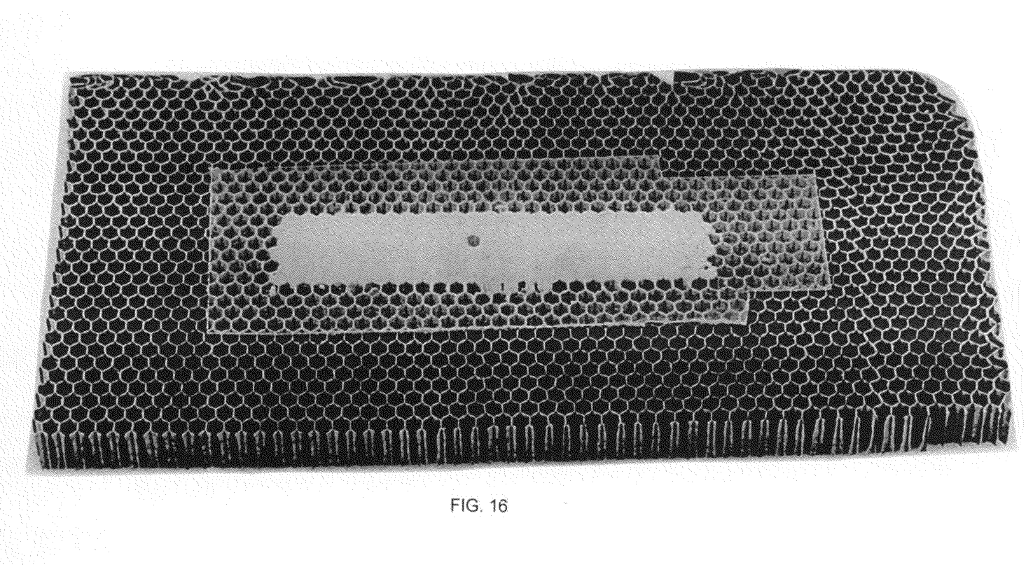

A plot of effective thermal conductivity measured by each element versus five percent penetration is shown in FIG. 10. Probe #9 is clearly affected by the waterslot; the neighbouring probes seem to be unaffected. The other probes group together quite well except for probe #5 at the end of the measuring period. The run time for this experiment was 1020 seconds. Equation 3 above gives a value of penetration along the CFRP layer of 3.1 cm for a 300 second experiment. This is in good agreement with the simulation result of FIG. 16 below where the 5% contour through the CFRP is 2.5 cm away from the hot wire. Slope values calculated for T.C. values and penetration positions shown on FIG. 11 are therefore taken at ln (time) values of 2.5, 3.5, 4.5, 5.5, (i.e. times of 12, 33, 90, and 246 seconds) to avoid significant probe interaction effects.

Probe #6 was 0.8 cm away from a vertical adhesive layer that was 1 mm thick. As shown in the graph in FIG. 10 that probe showed an increasing trend in the effective thermal conductivity measurement towards the conclusion of the experiment. This clearly shows sensitivity to even the thin adhesive layer which could potentially indicate a weak spot in the material.

For FIG. 10, Ke values are calculated from equation (3) at specific ln(t) values along the curves shown in FIG. 9. Probes #7 and #8 are in the uniform zone of the sample, and at each ln(t) value, the mean Ke value from probes #7 and #8 is used as Ke, ref to provide a normalized value Ke/Ke, ref for all probes. Equation (4) is used to calculate the 5% penetration distance along the CFRP layer for each probe at each ln(t) point, and this value is added to the probe distance from the left edge of the sample. The results clearly show high values of Ke/Ke, ref in the zone 6.6 cm to 8.9 cm due to the water slot and lesser high values in the zone 14 cm to 18 cm due to the weld zone at 13 cm. This is consistent with the high Ke/Ke, ref value of water displacing the usual foam in the large slot, and the slightly higher Ke/Ke, ref value due to the weld line material.

Three-point flexural deformation tests were conducted with a separate sample of the laminate. In this case a single element probe was used to measure Ke at a point 2.5 cm away from the curved area of the upper surface. The results in FIG. 11 show a significant lowering of Ke/Ke, ref in the tension zone below the top CFRP layer due to deterioration of the PVC and/or the interfacial bond between CFRP and PVC up to a 5% penetration into the PVC foam of 0.8 cm. Beyond that penetration point, the value of Ke/Ke, ref increases up to a value of 1.1, indicating that the temperature wave has moved into the denser crushed zone at a 5% penetration value of 1.1 cm.

### Simulation Work

To help prove the probe sensitivity to damage, simulation work was done to further investigate this method of flaw detection. FIG. 12 shows the grid with the details of the simulation input outlined in Tables 2 and 3.³

TABLE 2
Simulation Domain Properties

| | | |
|---|---|---|
| Overall Length (x-direction) | 55 | mm |
| Overall Height (y-direction) | 64 | mm |
| Nodal Distance (square array) | 0.02 | mm |
| Time step size | 1 | s |
| Probe heat input (both) | 2.26*10¹⁰ | W/m³ |
| Probe thickness (both) | 0.207 | microns |
| Probe width (leftmost probe) | 0.1 | mm |
| Probe width (rightmost probe) | 0.2 | mm |
| Distance between probes | 2.5 | cm |

TABLE 3
Thermal Properties Used in Simulation

| property | PVC^{a} | Biax^{b,e} | Probe^{c} | Water^{d} | PUR^{d} |
|---|---|---|---|---|---|
| k (W/mK) | 0.03 | 1.28(a), | 91.74 | 0.627 | 0.041 |
| | | 0.799(n) | | | |
| ρ (kg/m³) | 80 | 1530 | 8900 | 1027 | 15.8 |
| Cp (J/kgK) | 1750 | 1024 | 91.74 | 4213 | 1050 |

^{a}Diabgroup website⁴,
^{b}Bateman 2009³,
^{c}using Nickel properties supplied by the simulation software,
^{d}Bashar 2005²,
^{e}Vectorply website⁵

The simulation uses a symmetry axis to simulate the multiple probe operation, permitting three hot wire probes to be simulated at one time. The waterslot was incorporated by replacing the PVC properties by water properties in the slot region.

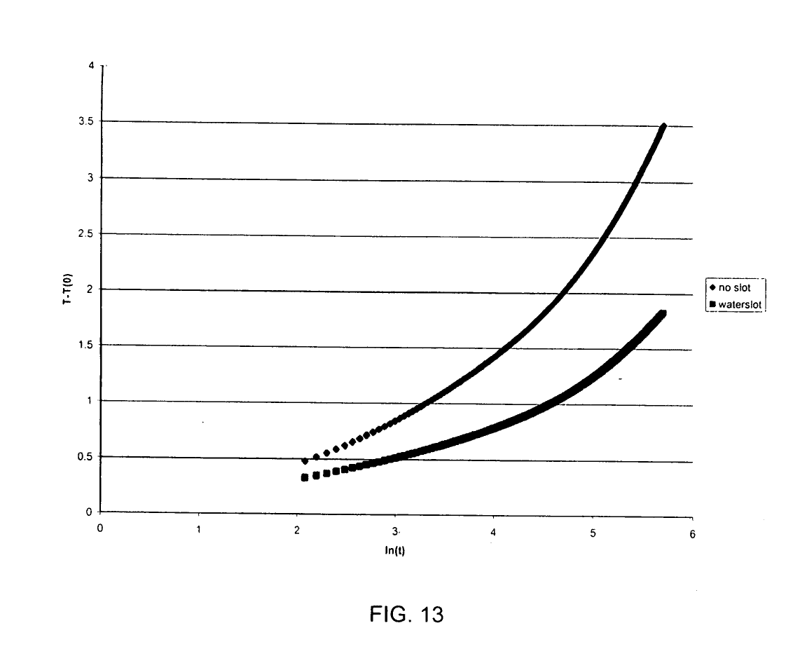

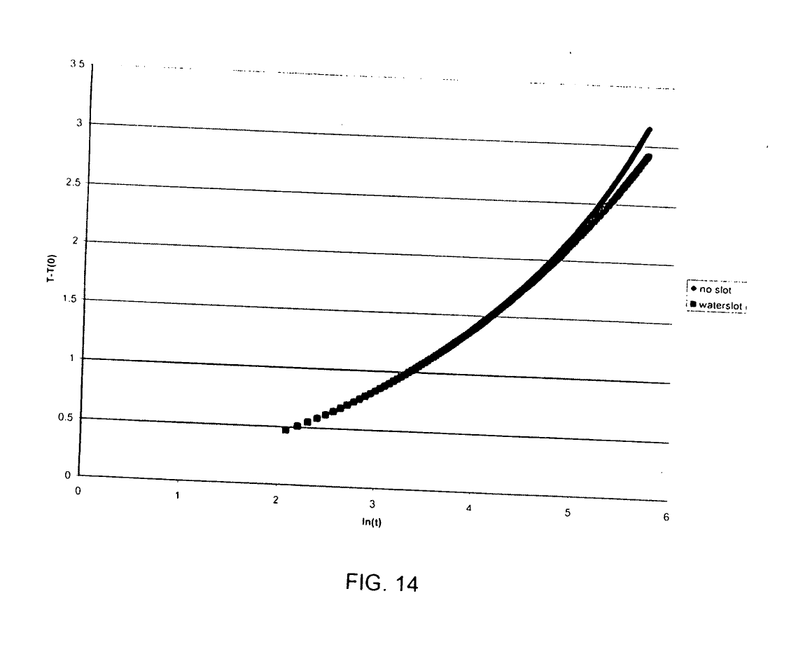

Plotted in FIGS. 13 and 14 are the temperature rise curves produced by the simulator. Likewise this shows sensitivity for the probe directly underneath the slot but the neighbouring probe only shows some slight sensitivity upon the conclusion of the run.

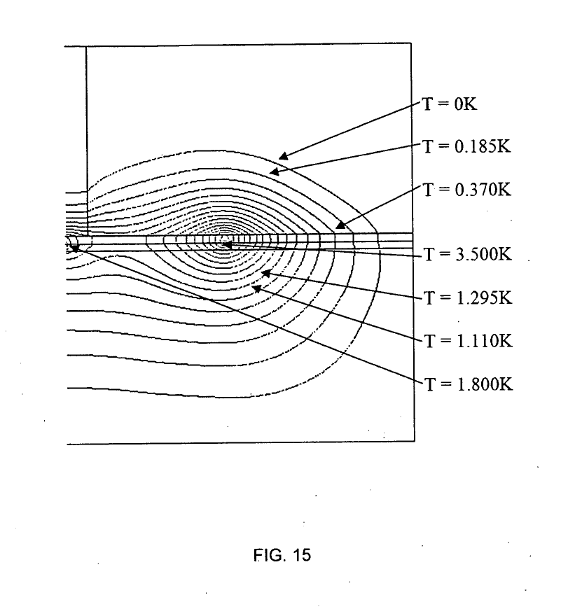

FIG. 15 shows a sample of the temperature contour produced by the simulator, as one would expect the probes do show signs of interaction as depicted by the temperature contour. The contour also shows why the neighbouring probe is not sensitive to the slot while the probe directly underneath the waterslot is quite sensitive, as it has remained colder than the probe adjacent to it. Temperature contours were simulated via FLUENT™ software for a 55 mm long by 32 mm high test sample (top segment of above diagram) which consists of a 30 mM thickness of Diab H80 structural foam core bonded to a Vectorply CBX-2400 bias ply carbon fiber/resin layer. The vertical line at top left shows the edge of a slot cut into the foam core which is filled with water gel. The sketch shows the right side of a three-probe array only since the left side is an exact mirror image of the above. The sample is placed over a three-probe hot wire array on a thin polyimide sheet which is fastened to a 30 mm thick polyurethane foam insulating backing layer. Temperatures indicated are in Kelvin degrees over the initial uniform temperature of 300 Kelvin (27 Celsius). All probes operate at a heat emission rate of 0.01 W/cm. The point indicated as 1.80 K is the probe under the water slot. The point indicated as 3.50 K is the probe 2.5 cm away from that location. The plot represents the temperature distribution through a cross-section of the assembly (perpendicular to the wire axis), at 300 seconds from start of heating. The temperature rise of the probe at the left edge of the plot reflects the presence of the watergel directly above the probe while that at the right has been only slightly affected.

This example shows that the multi-element hot wire probe is capable of being a non destructive test method for detecting flaws in carbon fibre re-enforced sandwich type material. The thermal conductivity measurement is quite sensitive as depicted in both the experimental observations and simulation work. The interactions with the hot wire elements with their neighbours give rise to the possibility of this multielement system to focus the heat production on a particular area and or generate a spread of heat input to generate a much larger detection envelope.

### Example 2

### Thermal Conductivity Tests to Detect Flaws in Structural Foam Core Materials

Honeycomb Structure with Void

Thermal conductivity (T.C.) tests were performed on a honeycomb core, a section of structural composite laminate, and Diab 80 foam core. A single hot wire probe element 1 cm in length was used at a typical constant heat emission rate of 1.0 W/m. The present example illustrates the utility of embodiments of the present invention for the sensitive detection of structural flaws in several different types of composite laminate structures. Measurements were also obtained for cylindrical samples of Diab H80 to show the effect of sample curvature on the results.

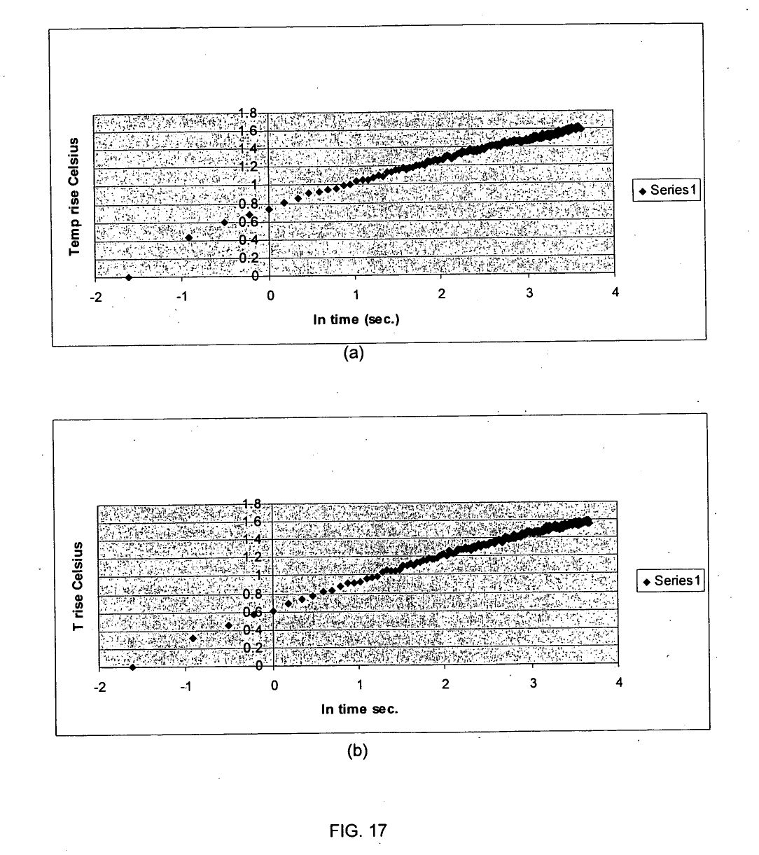

As shown in FIG. 16, a composite structure comprising a honeycomb core, with a 1.0 cm thickness and 3 mm diameter hexagonal cells, was measured. A 1 cm by 8 cm section of the core was filled with plastic wood, with one 3 mm hole missing to simulate a structural defect. FIG. 17 shows the resulting inferred temperature rise for the honeycomb structure, in which (a) the probe is positioned over a continuous portion of the plastic wood and (b) the probe is positioned over the 3 mm hole, where the calculated Ke values from ln(t)=0 to ln(t)=1 were 0.40 W/mC and 0.31 W/mC, respectively.

Note that the thermal conductivity reflects the presence of the hole in the plastic wood layer under the mactac strip. While a 5 cm long probe does not have the sensitivity to detect a single hole, it can easily detect a 3 mm wide strip of empty cells across the plastic wood layer.

### Detection of Delamination in Composite Laminates

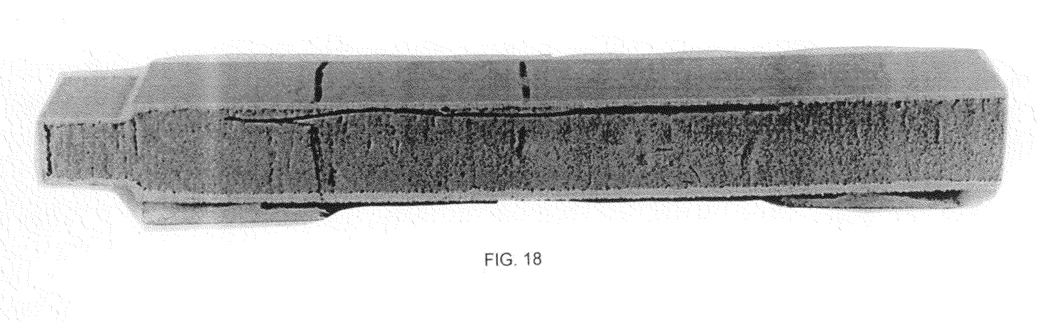

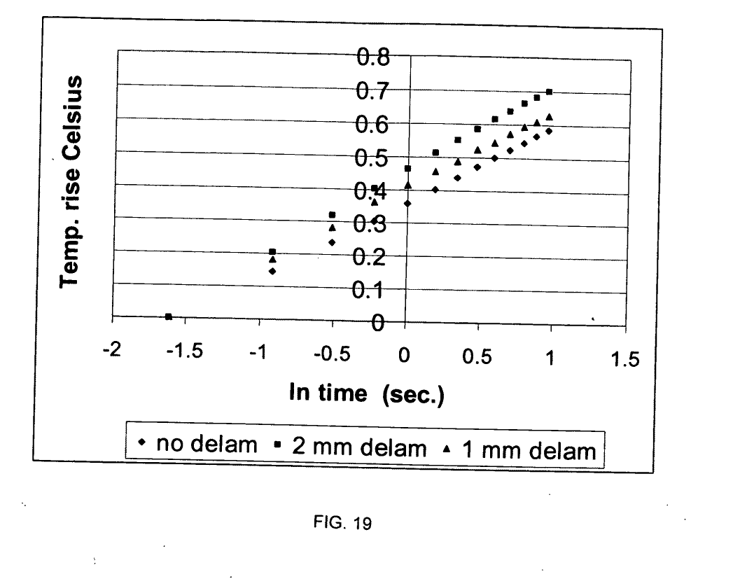

The effect of local delamination on the thermal conductivity was investigated by measuring the sample shown in FIG. 18. As can be clearly seen in FIG. 19, the delaminations cause an initial temperature rise at time less than 1.0 second, with the rise being proportionate to the delamination gap. This result underlines the utility of embodiments of the invention for the identification of delamination defects in composite laminate structures.

### Voids in Foam Core Material

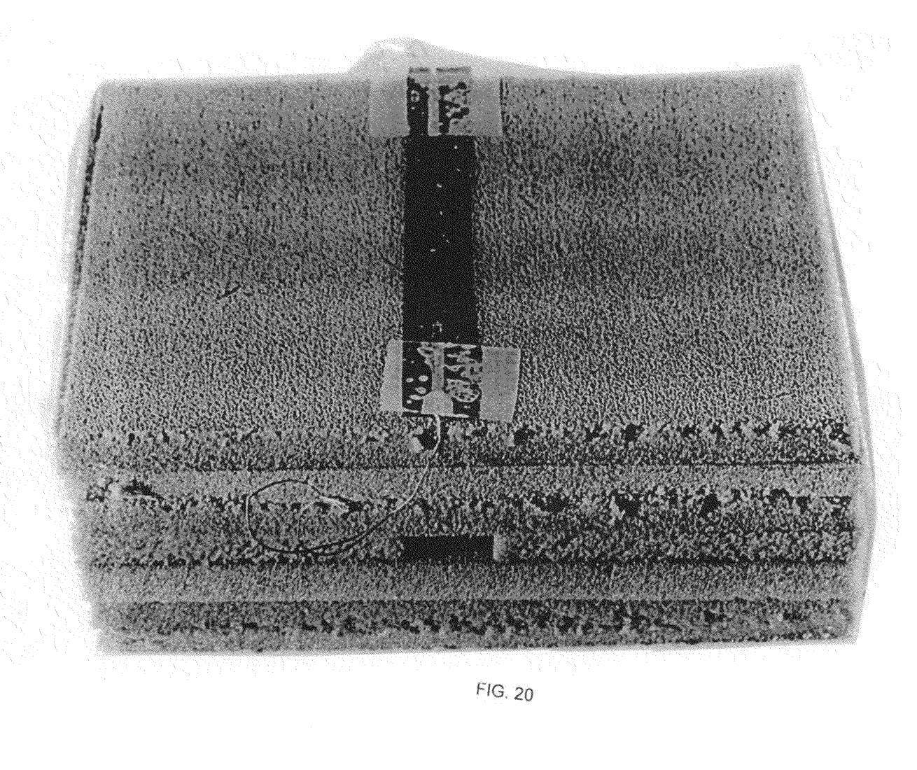

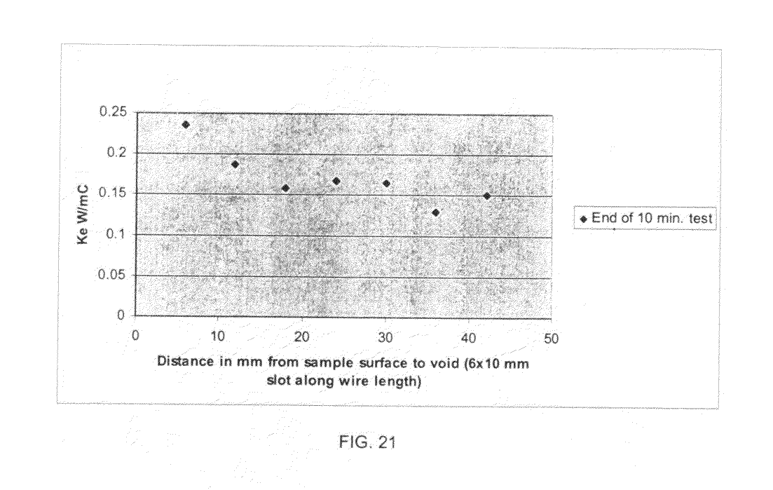

As can be seen in FIG. 20, a movable slot was introduced under the probe/sample interface in a composite laminate sample, and T.C. measurements were performed when the slot was moved closer to the surface. As evidenced in FIG. 21, the sensitivity for a ten minute test is for up to 25 mm away from the surface. The T.C. value for a uniform H80 sample is 0.12 W/mC. The effective T.C. increases as the slot is moved closer to the heated surface because the slot is open at the ends in this case and natural convection of the air in the slot causes additional cooling. Note that the foam backing has been removed from the hot wire in this view.

### Effect of Sample Curvature

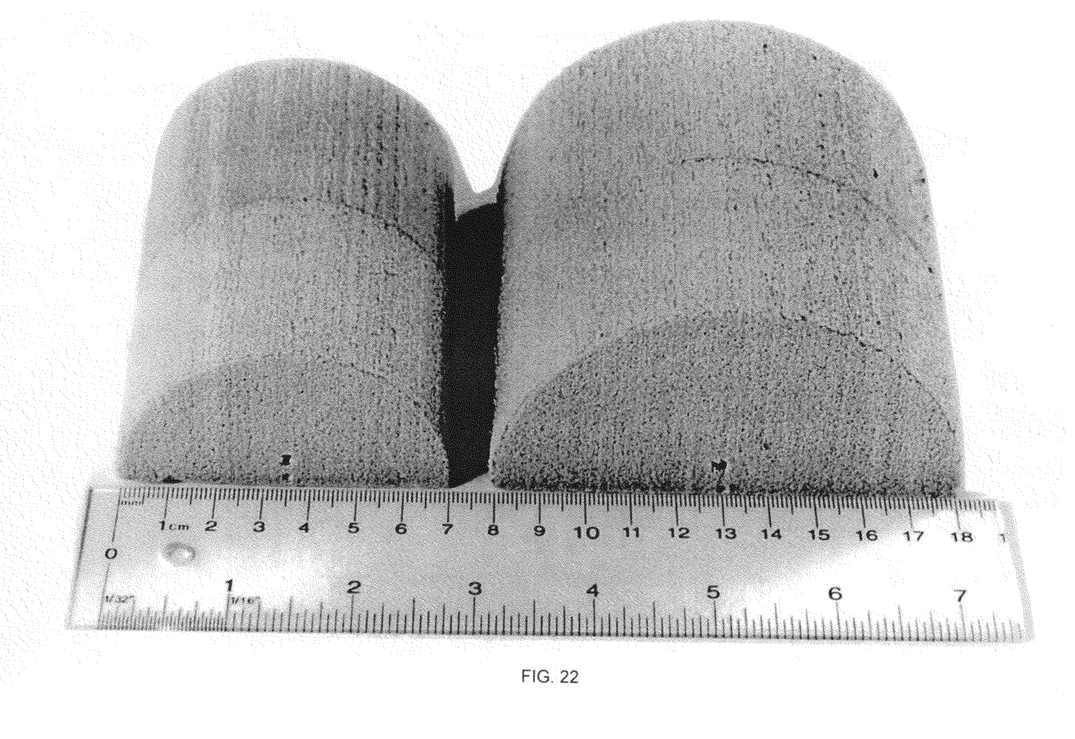

The effect of sample curvature on the inferred thermal conductivity was investigated by performing T.C. measurements on two Diab H80 half cylinders (65 mm and 100 mm diameter respectively) measured with the hot wire placed along the curved surface in a direction parallel to the axis, as well as along the flat bottom surface. These cylinders are shown in FIG. 22.

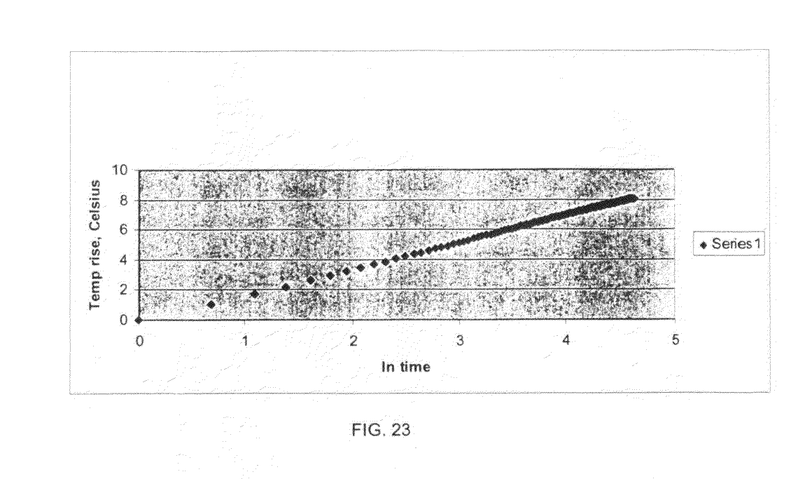

FIG. 23 shows the test results at a current of 0.020 amps for 100 seconds. There is a slight reduction in slope beyond ln t of 4 probably due to the sample losing heat from the flat surface opposite the probe. Results for the 100 mm Diab cylinder are 1.87, which can be compared to a flat surface, with a result of 1.82 for same time period. These are minor differences and correction charts can be calculated for greater curvature effects at smaller diameters.

### Example 3

### Application of Method for Process Control of Low Thermal Conductivity Materials

### Summary

Probe designs disclosed in previous embodiments of the invention typically use a backing material (polyurethane foam) with a thermal conductivity (T.C.) of about 41 mW/mK. Vacuum Insulated Panel (VIP) products use superinsulation materials (e.g. fumed silica) with T.C. values in the order of 5 mW/mK when under high vacuum conditions. Measurements with the foam-backed probes many not be sufficiently sensitive for suitable process control. In preliminary experiments, it was found that 52% of the heat generated was absorbed by the foam backing and the foil laminate envelope material used in the VIP.

Simulation via FLUENT™ was used to optimize design parameters. Accuracy of the optimization was proven by comparing results with experiment when an Aerogel sample at atmospheric pressure was measured using the immersed hot wire method. Excellent agreement was found between the two, thus validating the simulation procedure.

Simulation was done for the unguarded and guarded wire systems based on an evacuated VIP backing with an internal T.C. of 5 mW/mK using a range of T.C. sample values (5, 10, and 27.6 mW/mK). The unguarded case showed a greater sensitivity. Furthermore, this approach gives T.C. directly, whereas the unguarded method gives the effusivity (ρ. k. Cp)^{1/2}.

Accordingly, in a preferred embodiment of the invention, in which a probe is used for the process control and/or detection of defects in low thermal conductivity materials, one concludes that the probe should be unguarded. In a preferred embodiment, a probe has a 5″ by 5″ by 0.5″ thick VIP base four using four 5 cm long hot wire elements spaced 1″ apart. This will provide simultaneous scanning of a significant area. Two-minute scan periods are recommended. Where panels are quite large, the system can easily be increased in size using more elements.

### Experimental and Numerical Simulation Results

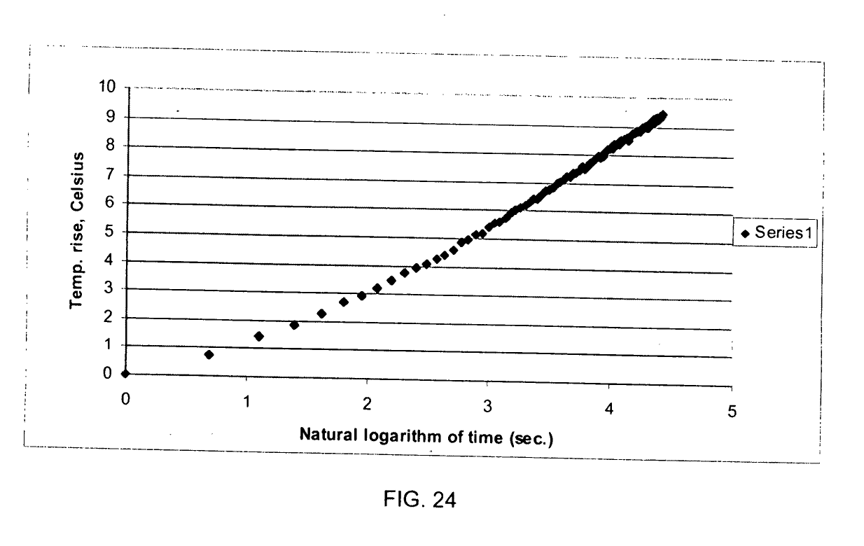

A sample of Nanogel (Cabot Corp. fumed silica Grade TLD201 Aerogel at atmospheric pressure) was placed into a test container containing a bare hot wire probe such that the probe was completely immersed in the Aerogel. A constant current of 0.020 amps was passed through the wire for a period of 80 s. The temperature rise with time is shown in FIG. 24.

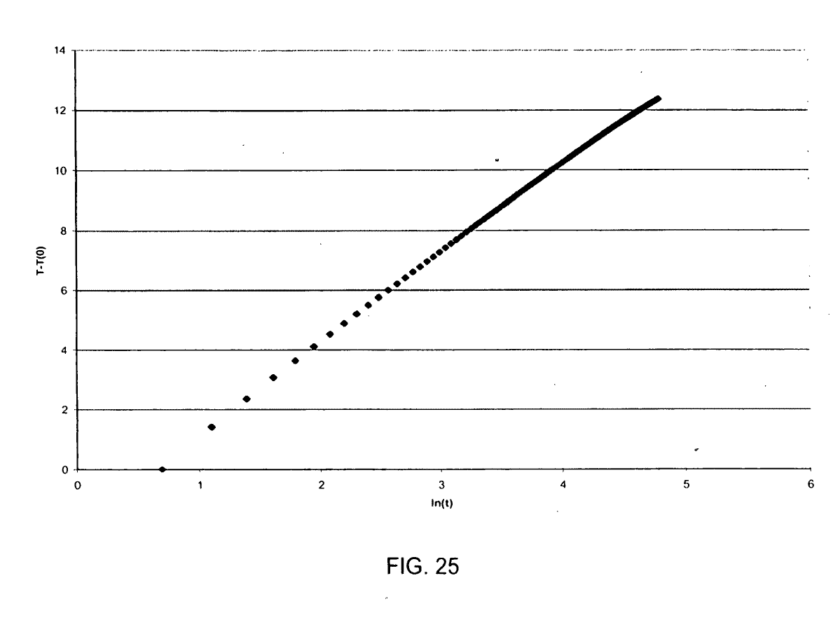

The above experiment was simulated via FLUENT™ software with actual wire heating conditions and dimensions. The result is shown in FIG. 25, which, as shown in Table 4 below, closely matches the experimental results.

TABLE 4
Slope and k_{eff} Calculation Results and Comparison

| | Simulation | Experimental | Units |
|---|---|---|---|
| Slope | 2.893 | 2.85 | |
| k_{eff} | .0275 | .0276 | W/mK |
| R\hat{ }2 | 1.000 | 0.997 | |

Slopes were calculated for the period 35 to 80 seconds. Agreement between experiment and simulation is excellent, therefore simulation will be used in design considerations given below.

### Sensitivity of Unguarded Vs Guarded Wire Experiments

A single hot wire is typically termed an “unguarded” hot wire. A “guarded” hot wire is one which is accompanied by identical hot wires situated on each side of it and parallel to it, and generating the same quantity of heat. The guarded approach can be arranged to produce a flat temperature profile advancing into the sample, and is used to measure effusivity, from the slope of temperature rise vs the square root of time. Here we simulate both guarded and unguarded experiments to determine whether or not one has an advantage over the other in determining thermal conductivity of a sample. The wire-to-wire separation in the guarded separation is set at 6 mms in this study, and results are presented below in tables 6 and 7. The cases studied are for a vacuum insulated panel (VIP) of Nanogel with T.C. of 5 mW/mK with samples of material with T.C. values of 5 mW/mK, 10 mW/mK, and 27.6 mW/mK respectively. The polyimide film wire support film and the VIP envelope of laminated polymer and aluminum foil are included in the calculation.

In the simulations, the film properties for the immersed probe simulation are set to polyimide; for the sensitivity analysis with the fixed backing of 5 mW/mK the film properties are changed to the aluminum-PET foil properties (see table 5). The probe and guard heat inputs were set to 1 W/unit length (m) of probe. 40 iterations per time step were employed, and the time step size of 1 second produced energy residuals of <1e-8 Joules. Foil properties were obtained by applying the mixing rule for density, heat capacity and axial thermal conductivity (aluminum accounts for about 8% of the material with the remaining being PET); the normal conductivity is assumed to be governed by the PET and is set to that thermal conductivity. Aluminum properties obtained using FLUENT™ database were as follows: ρ=2719 kg/m³, Cp=971 J/kgK, k=202.4 W/mK; PET values: ρ=1400 kg/m³, Cp=1275 J/kgK, k=0.31 W/mK.

TABLE 5
Material Properties Used in the Simulation

| Material | ρ (kg/m³) | Cp (J/kgK) | k(W/mK) |
|---|---|---|---|
| Polyimide | 1420. | 1130 | 0.23 |
| Foil | 1557 | 1243 | 18.3(a), 0.31(n) |
| Nanogel | 65 | 925 | varied |

TABLE 6
Slope Results for the Unguarded Simulations

| | 5 mW/mK | 10 mW/mK | 27.6 mW/mK | units |
|---|---|---|---|---|
| Slope | 10.222 | 8.424 | 5.087 | |

TABLE 7
Slope and Results for the Guarded Simulations

| | 5 mW/mK | 10 mW/mK | 27.6 mW/mK | Units |
|---|---|---|---|---|
| Slope | 4.339 | 3.744 | 2.702 | |

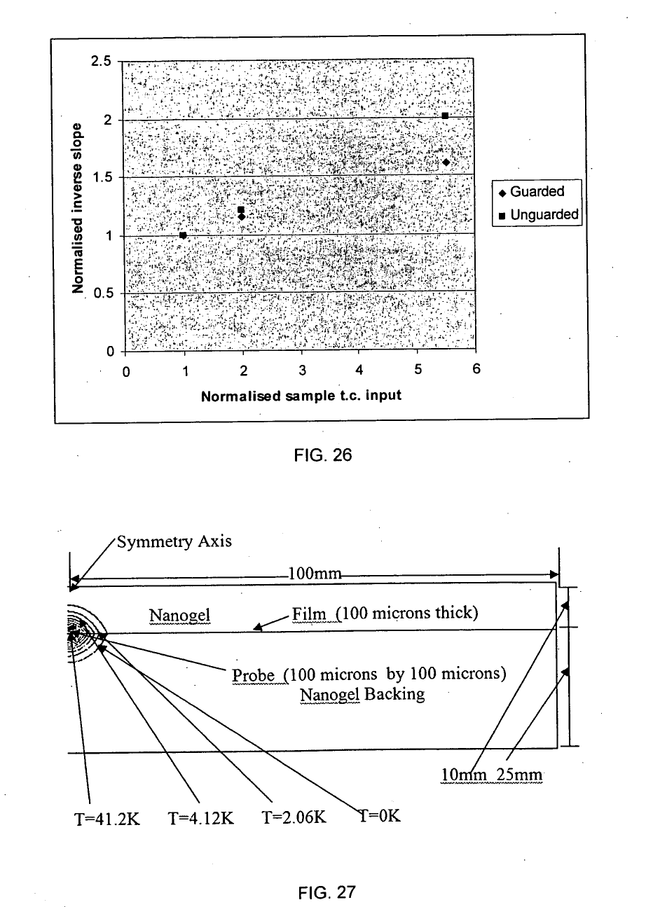

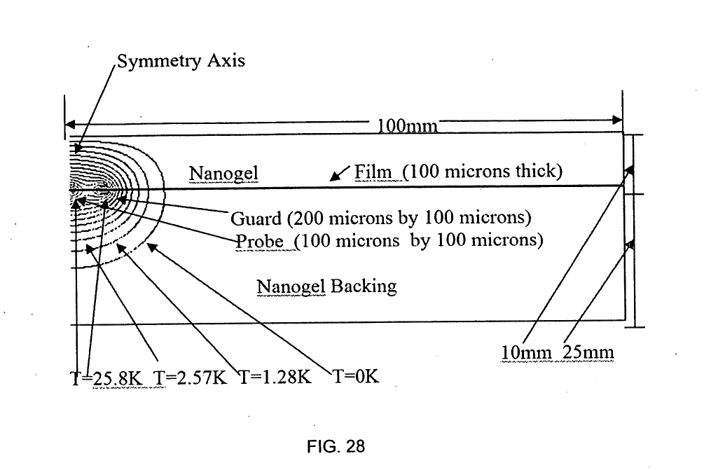

These data are presented in graphical fashion in FIG. 26, using a normalizing method where the sample T.C. value is presented by its relationship to the T.C (5 mW/mK) of the probe backing (support base) material, Nanogel. That is the 5 mW/mK is represented by 1, the 10 mW/mk by 2, etc. Since the inverse of the slope is used to calculate thermal conductivity or effusivity (where temperature is plotted against square root of time), it is that value which is presented in normalized form. Contour plots of the simulated temperature profiles of guarded and unguarded probes are shown in FIGS. 27 and 28.

Based on the simulation results, the unguarded measurement allows for greater resolution in detecting differences in sample thermal conductivity. In addition, it avoids the need to evaluate density and specific heat which are part of the effusivity (ρ.Cp.k)^{1/2} which is the result obtained from the inverse slope of the guarded experiment.

Simulation shows also that the lowest possible thermal conductivity material should be used in the wire support (backing). The 5 mW/mK value is typical value available in VIP products.

### Example 4

### Sensitivity, Heating and Cooling Rates, and Effect of Contact Resistance

### Measurement Sensitivity

With a probe backing of VIP with a T.C. of 0.005 W/mC, simulations were performed using the FLUENT™ software package. T vs ln(t) curves were obtained for a variety of T.C. sample values ranging from 0.01 to 0.005 W/mC.

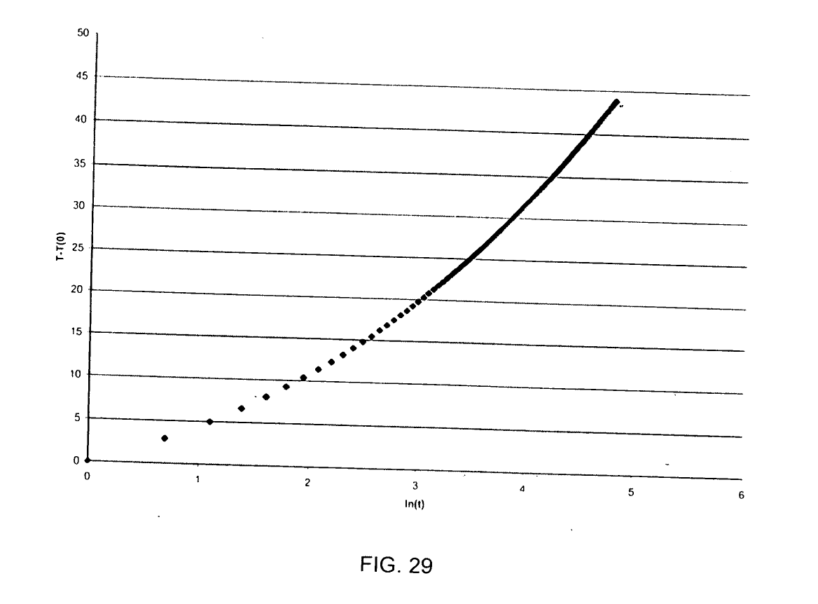

FIG. 29 shows simulated temperature rise results for the case of 0.5*10⁻³ W/mK. Table 8 provides the slope obtained from the temperature rise curves provided by FLUENT™.

TABLE 8
Slope vs. Input Core Thermal Conductivity

| Input core | |
|---|---|
| thermal conductivity | Resulting |
| [W/mK] | slope |
| 27.6*10⁻³ | 5.087 |
| 10*10⁻³ | 8.424 |
| 5*10⁻³ | 10.222 |
| 0.5*10⁻³ | 14.47 |
| 0.05*10⁻³ | 15.66 |
| 0.025*10⁻³ | 15.82 |
| 0.01*10⁻³ | 15.98 |
| 0.0025*10⁻³ | 16.12 |
| 0.001*10⁻³ | 16.2 |

It should be noted that the slopes calculated above were taken from t=33 seconds (ln (33) ˜3.50) to the end of the experiment which is t=120 s (ln (120) ˜4.79).

Table 9 shows the amount of heat absorbed by the core material for select cases:

TABLE 9
a: Heat Absorption Data Part One

| Material | 10 * 10⁻³ W/mK | | 0.5 * 10⁻³ W/mK | | 0.05 * 10⁻³ W/mK | |
|---|---|---|---|---|---|---|
| Name | Absorbed | % | Absorbed | % | Absorbed | % |
| Foil | 1.94284 | 32.97085 | 2.855538 | 46.65857 | 3.124276 | 51.48714 |
| Back | 1.6939 | 28.74622 | 2.405 | 39.29692 | 2.6 | 42.84723 |
| Core | 2.19791 | 37.29949 | 0.78 | 12.74495 | 0.26 | 4.284723 |
| Source | 0.05795 | 0.98344 | 0.079534 | 1.299563 | 0.083794 | 1.380904 |
| Total | 5.8926 | | 6.120072 | | 6.06807 | |

b: Heat Absorption Data Part Two

| | | |
|---|---|---|
| Material | 0.025 * 10⁻³ W/mK | 0.01 * 10⁻³ W/mK |

| Name | Absorbed | % | Absorbed | % |
|---|---|---|---|---|
| Foil | 3.171609 | 52.41488 | 3.218786 | 52.77809 |
| Back | 2.6 | 42.96831 | 2.665 | 43.69772 |
| Core | 0.195 | 3.222623 | 0.13 | 2.131596 |
| Source | 0.084362 | 1.394193 | 0.08493 | 1.392591 |
| Total | 6.050971 | | 6.098716 | |

c: Heat Absorption Data Part Three

| | | |
|---|---|---|
| Material | 0.0025 * 10⁻³ W/mK | 0.001 * 10⁻³ W/mK |

| Name | Absorbed | % | Absorbed | % |
|---|---|---|---|---|
| Foil | 3.234823 | 53.46657 | 3.604144 | 56.1412 |
| Back | 2.665 | 44.04828 | 2.665 | 41.5123 |
| Core | 0.065 | 1.074348 | 0.065 | 1.012495 |
| Source | 0.085356 | 1.410804 | 0.08564 | 1.334004 |
| Total | 6.050179 | | 6.419784 | |

The most relevant information contained in Table 9 is the percentage of the total amount of energy absorbed by the core. The hot wire probe becomes insensitive to the properties of the core layer below a T.C. of 0.5*10⁻³ W/mK. Table 9 shows that the slope changes 21% for a core T.C. change from 0.01 to 0.005 W/mC and changes 42% for a core T.C change from 0.005 to 0.0005 W/mC. As one skilled in the art will appreciate, this is adequate sensitivity for process control applications in industry.

### Heating and Cooling

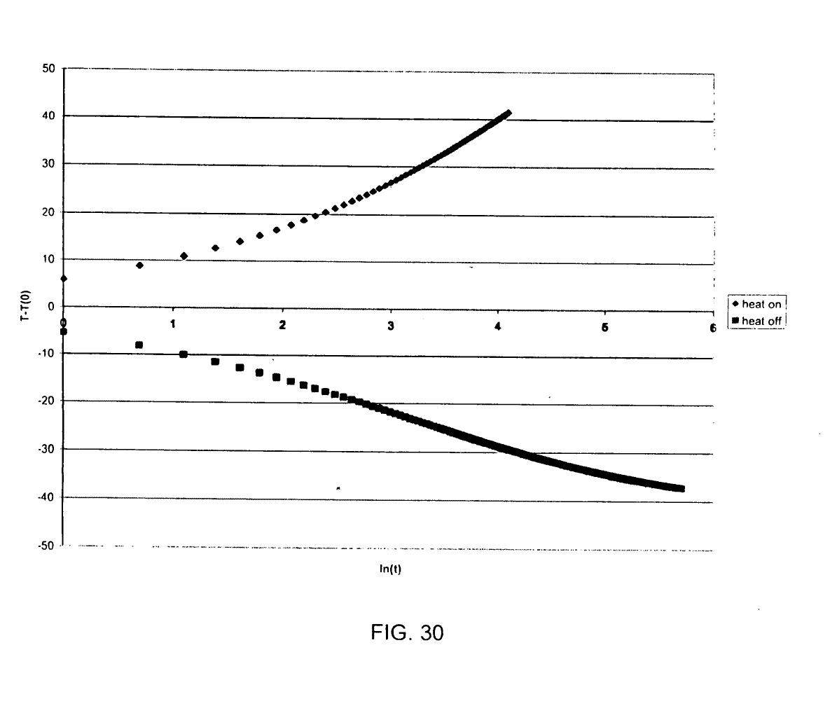

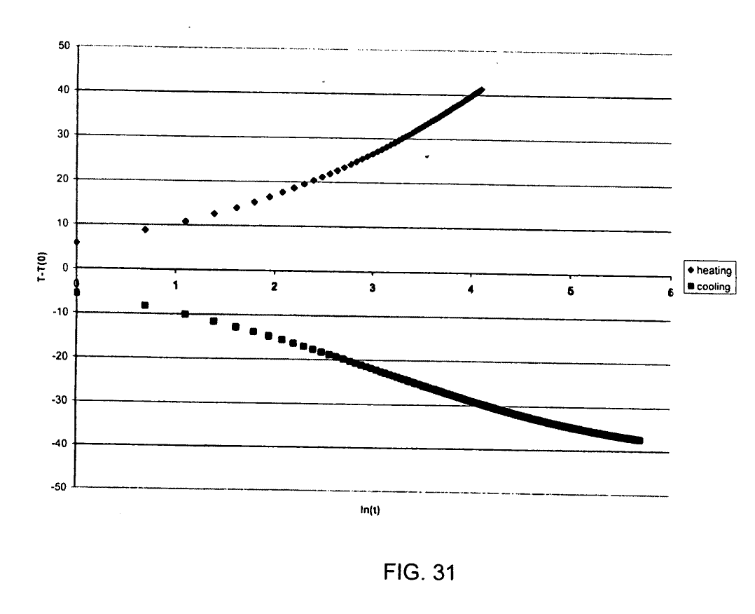

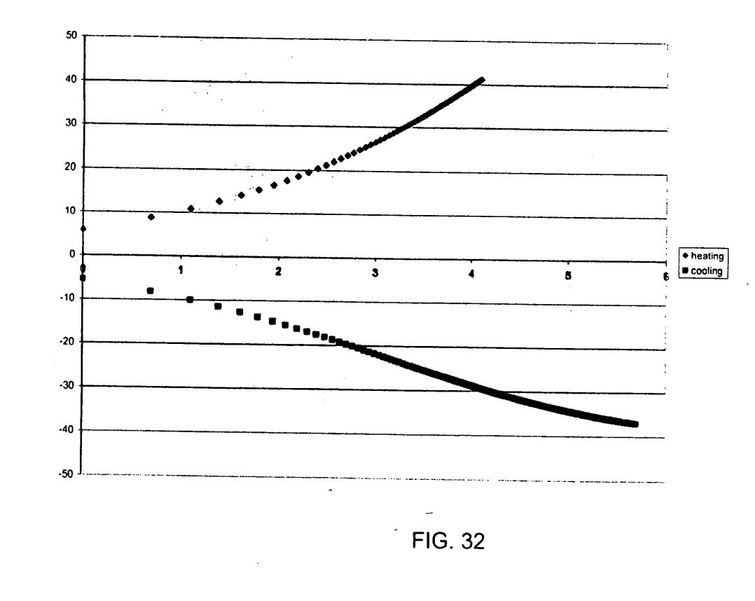

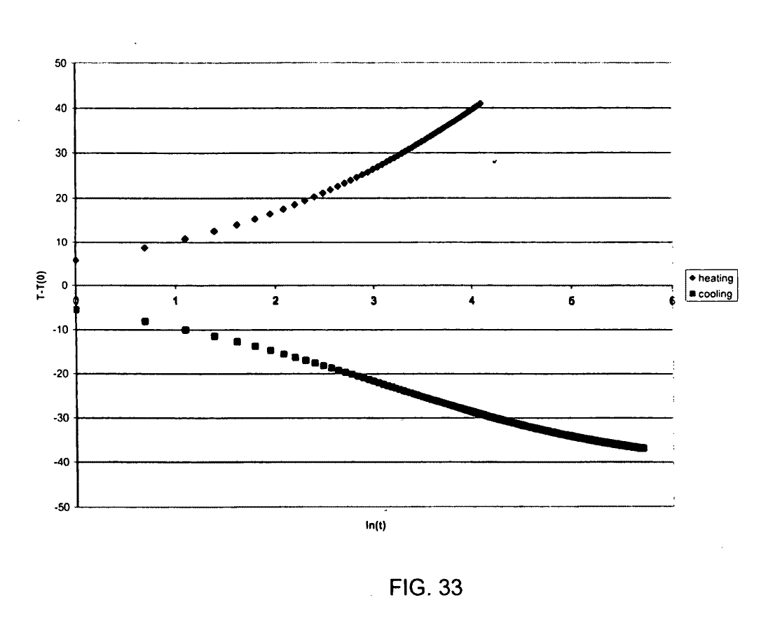

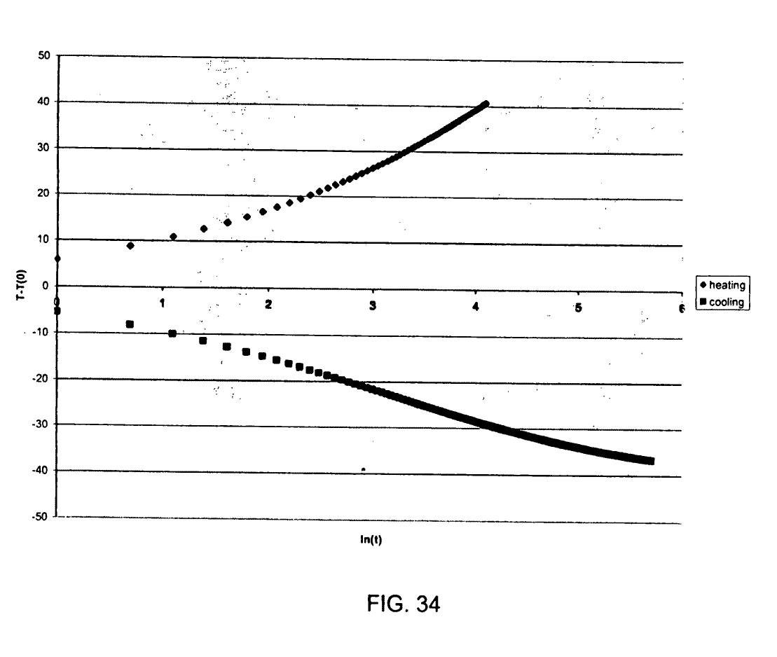

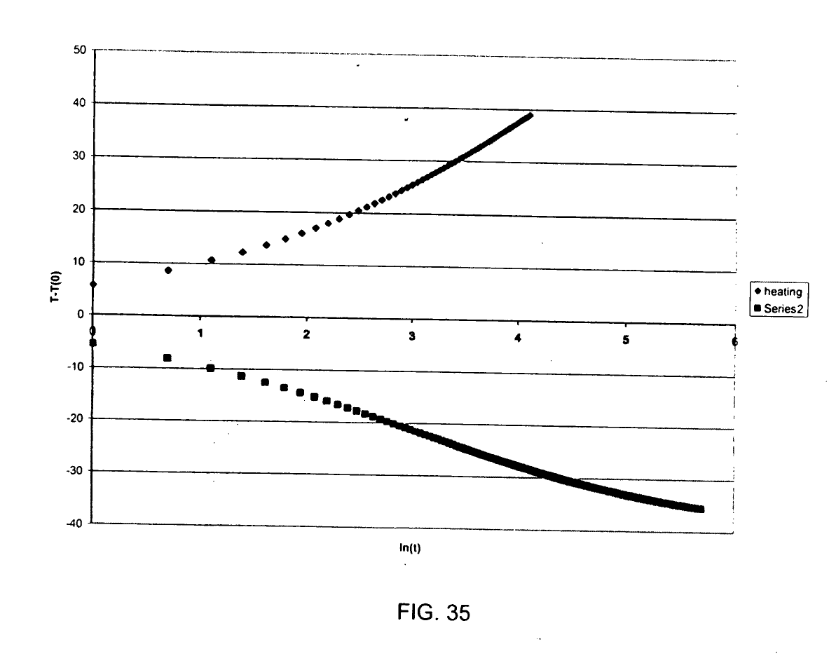

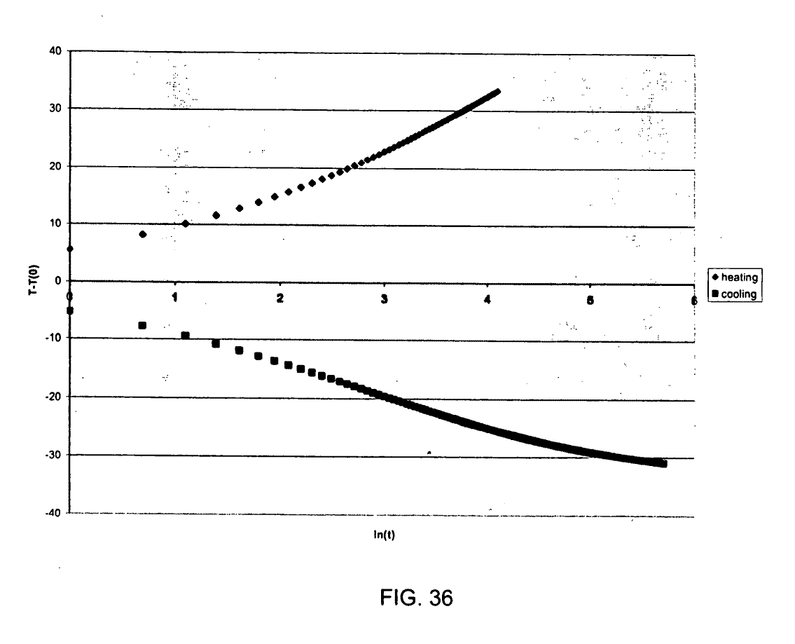

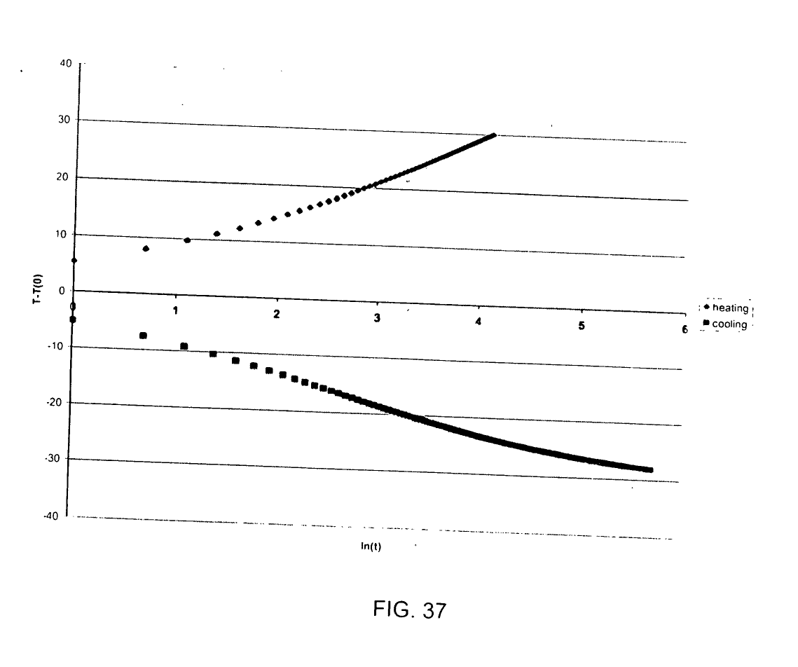

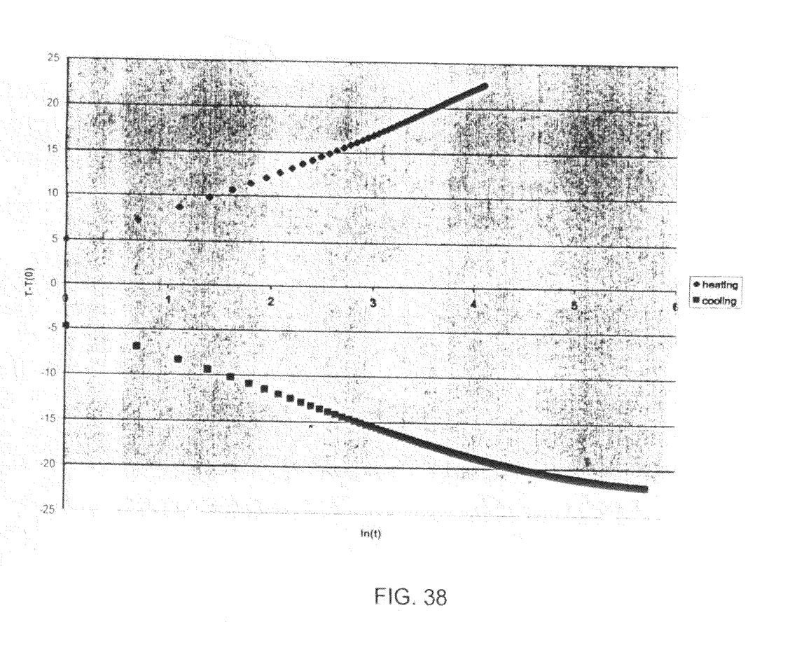

Shown graphically in FIGS. 30 through 38 are the simulated heating and cooling curves for a case where, the probe has taken readings for one minute and allowed to cool for 5 minutes (a six minute cycle). These simulations were all done with the 5*10⁻³ W/mK backing (same as the backing for the sensitivity analysis outlined above).

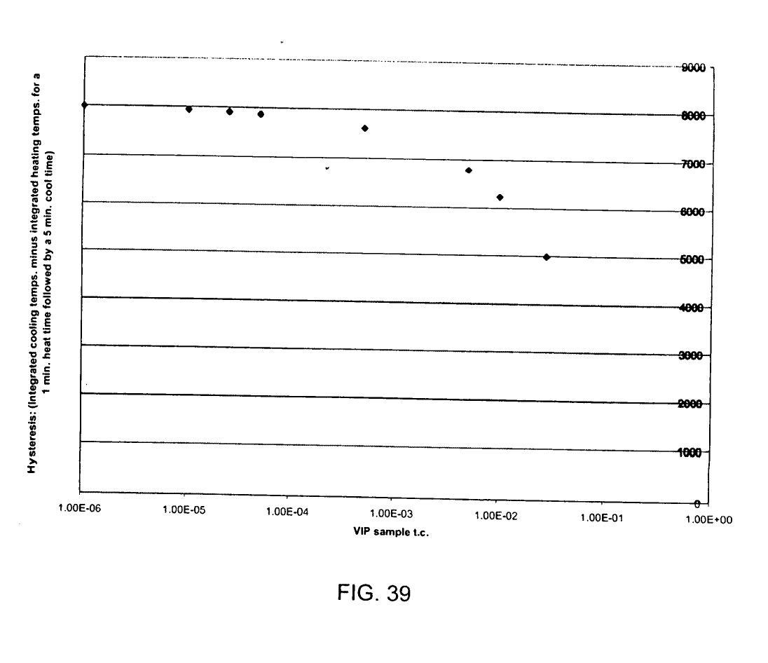

The hysteresis effect analysis is shown in FIG. 39. Here it can be seen that there is some effect by the sample thermal conductivity but is not as sensitive to the direct measurement approach. Specifically, for an order of magnitude change in thermal conductivity in the same range of conductivities used for the lower limit analysis, only an 8.8% change is exhibited.

### Contact Resistance

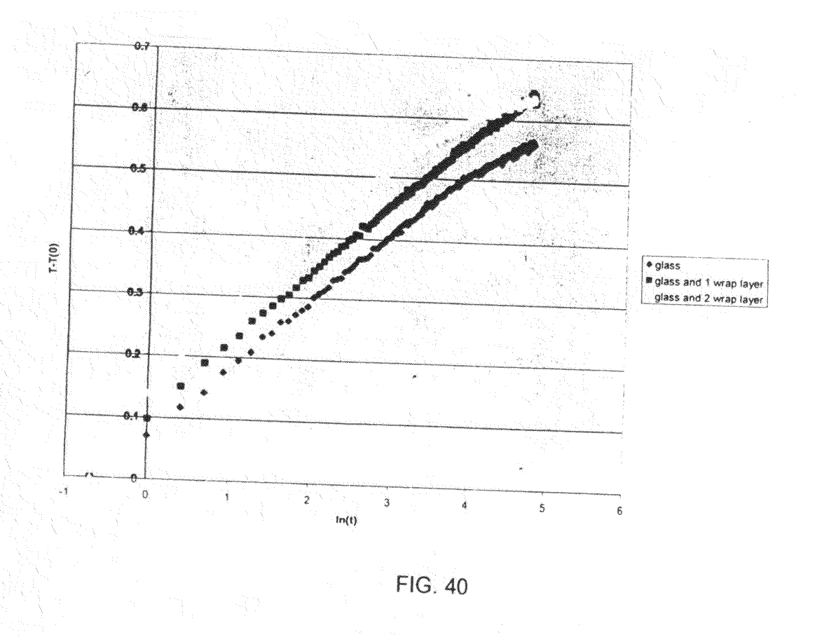

FIG. 40 shows graphically the experimental results for contact resistance tests. This experiment was done by simply placing a piece of PYREX glass on the hot wire probe that is mounted on polyurethane foam and letting it run for two minutes. Then as the probe is cooling the glass is then wrapped in a layer of shrink wrap and the experiment is repeated. Finally after the second run the glass is wrapped in a second layer of the shrink wrap and the experiment is repeated one more time. For each experiment, the sample is weighed down by a 250 gram weight.

Table 10 shows the slope results of the three curves with each slope taken on the interval of ln(t)=2 to ln(t)=3.

TABLE 10
Slope Results for Contact Resistance Experiments

| | glass | Glass | Glass |
|---|---|---|---|
| | only | 1 wrap | 2 wrap |
| Slope | 0.1100 | 0.1129 | 0.1061 |
| R\hat{ }2 | 0.9946 | 0.9955 | 0.9930 |

Although the temperature shows a dependency on the number of wrap layers, the slopes taken from the interval clearly do not. The contact resistance of the layers therefore does not affect the thermal conductivity result. This is the nature of the transient method, that the properties of the materials very close to the probe surface gradually become unimportant to the T vs ln(t) slope as time increases.

As used herein, the terms “comprises”, “comprising”, “including” and “includes” are to be construed as being inclusive and open ended, and not exclusive. Specifically, when used in this specification including claims, the terms “comprises”, “comprising”, “including” and “includes” and variations thereof mean the specified features, steps, processes or components are included. These terms are not to be interpreted to exclude the presence of other features, steps or components.

The foregoing description of the preferred embodiments of the invention has been presented to illustrate the principles of the invention and not to limit the invention to the particular embodiment illustrated. It is intended that the scope of the invention be defined by all of the embodiments encompassed within the following claims and their equivalents.

### REFERENCES

1. Carslaw, H. S., and J.C. Jaeger, Conduction of Heat in Solids, Oxford University Press, (1986), p. 75
2. Bashar, M. T., “Thermal Conductivity Probes for Fiber/Polymer Composites”, Master's Thesis, May 2005, UNB Chemical Engineering Department.
3. Bateman, R., “Thermal Conductivity Probes to Detect Flaws in Carbon Fibre/Polymer/Structural Foam Laminates”, Ph.D. Thesis, University of New Brunswick, Department of Chemical Engineering, 2009.
4. Diabgroup Website, online Divinycell H properties pdf, http://www.diabgroup.com/americas/u_products/u_prods 2.html.
5. Vectorply Website, online C-BX 2400 properties pdf, http://www.vectorply.com/pdf/c-bx%202400.pdf.

Therefore what is claimed is:

1. A device for the non-destructive testing of a composite laminate material, said device comprising:
a) an array of elongate conductive resistance elements affixed to a surface of an insulating substrate, said elements being spaced a known distance from each other, said insulating substrate supported by an insulating backing material, and said elements having a composition and cross-sectional dimensions selected to generate heat when an electric current is passed therethrough;
b) a power supply, said elements being connected to said power supply for supplying electrical current thereto to provide a controlled rate of heat generation when said array is contacted with an outer surface of said composite laminate material;
c) means for measuring a time-dependent resistance of each said element when said electrical current is supplied to each said element; and
d) a computer control means being connected to said power supply and said means for measuring a time-dependent resistance, said computer control means programmed to monitor and record changes in said resistance of said each element with time and provide an output related to an effective thermal conductivity of said composite laminate near each said element.

2. The device according to claim 1 wherein said computer controller means is programmed to apply current to each said element either simultaneously or sequentially according to another prearranged sequence.

3. The device according to claim 1 wherein said insulating substrate is flexible and can be shaped to contact said array with a non-planar composite laminate material.

4. The device according to claim 1 wherein said computer control means is programmed to provide a controlled rate of heat generation of each element with time which is a pre-selected constant rate of heat generation.

5. The device according to claim 1 wherein said computer control means is programmed to provide a controlled rate of heat generation of each element with time which is a pre-selected variable rate of heat generation.

6. The device according to claim 1 wherein said insulating backing material is a polyurethane foam.

7. The device according to claim 1 wherein a length of said elements is within the range of approximately 1 to 5 cm.

8. The device according to claim 1 wherein said insulating substrate comprises a polyimide film.

9. The device according to claim 1 wherein said each element comprises a ribbon having a width greater than approximately 100 microns and a thickness less than approximately 1 micron.

10. The device according to claim 9 wherein said each element comprises a nickel alloy.

11. A method for probing the structural integrity of a composite laminate, said method comprising the steps of:
a) contacting a probe with a surface of said composite laminate, said probe comprising at least one conductive resistance element affixed to a surface of an insulating substrate, said insulating substrate supported by an insulating backing material, and said element having a composition and cross-sectional dimensions selected to generate heat when an electric current is passed therethrough;
b) applying a current to said element for a time duration and measuring a voltage of said element while applying said current;
c) processing said time-voltage measurements to obtain an output measure related to an effective thermal conductivity of said sample, and
d) comparing said output measure to an expected value and inferring the presence or absence of a structural defect beneath said surface of said composite laminate.

12. The method according to claim 11 wherein said output measure is selected from the list comprising a dependence of voltage on time, a slope of a logarithmic graph of voltage vs. time, a dependence of resistance on time, a slope of a logarithmic graph of resistance vs. time, a dependence of temperature on time, a slope of a logarithmic graph of temperature vs. time, a dependence of effective thermal conductivity on time, and a dependence of effective thermal conductivity on an inferred thermal depth.

13. The method according to claim 12 wherein said inferred thermal depth corresponds to a 5% temperature depth.

14. The method according to claim 12 wherein said dependence is provided in graphical form.

15. The method according to claim 12 wherein said slope is obtained between approximately two and four log units.

16. The method according to claim 11, wherein said steps are repeated one or more times after translating said probe to a different spatial location on said surface of said composite laminate.

17. The method according to claim 11 wherein said probe comprises a plurality of said elements and wherein an output measure is obtained for each of said elements, and wherein the presence of a defeat is inferred by correlating said output measures with a spatial location of said elements.

18. The method according to claim 12 wherein said expected value is obtained by calculating a mean value of non-outlier output measures.

19. The method according to claim 11 wherein said expected value is a reference value for said composite laminate.

20. The method according to claim 11 wherein said expected value is obtained by numerical simulation.

21. The method according to claim 11 wherein said current is applied to provide a controlled rate of heat generation with time which is a pre-selected constant rate of heat generation.

22. The method according to claim 11 wherein said current is applied to provide a controlled rate of heat generation with time which is a pre-selected variable rate of heat generation.

23. The method according to claim 11, wherein steps b)-d) are performed by a control means, said control means comprising a computer readable medium encoded with computer-executable instructions, said control means further adapted to control said current applied to said element and to measure said voltage of said element.
